(19) United States
(12) Patent Application Publication
(10) Pub. No.: US 2021/0319833 A1
(43) Pub. Date: Oct. 14, 2021

(54) APPARATUS AND METHODS FOR QUARTER BIT LINE SENSING

(71) Applicant: SanDisk Technologies LLC, Addison, TX (US)

(72) Inventor: Hiroki Yabe, Yokohama (JP)

(73) Assignee: SanDisk Technologies LLC, Addison, TX (US)

(21) Appl. No.: 16/845,249

(22) Filed: Apr. 10, 2020

(51) Int. Cl. G11C 16/26; G11C 16/04; G11C 16/10; G11C 16/24; G11C 16/34

(52) U.S. Cl. CPC G11C 16/26; G11C 16/0483; H01L 27/11556; G11C 16/24; G11C 16/3459; G11C 16/10

(57) ABSTRACT

An apparatus is provided that includes a plurality of non-volatile memory cells, a plurality of bit lines, a plurality of memory holes, and a control circuit. The plurality of memory holes each include a corresponding one of the memory cells. Each memory hole is associated with and coupled to a corresponding one of the bit lines. The control circuit is configured to read the memory cells in four separate read intervals.

### BACKGROUND

Semiconductor memory is widely used in various electronic devices such as cellular telephones, digital cameras, personal digital assistants, medical electronics, mobile computing devices, servers, solid state drives, non-mobile computing devices and other devices. Semiconductor memory may comprise non-volatile memory or volatile memory. A non-volatile memory allows information to be stored and retained even when the non-volatile memory is not connected to a source of power (e.g., a battery). Examples of non-volatile memory include flash memory (e.g., NAND-type and NOR-type flash memory).

Memory systems can be used to store data provided by a host device (or other client). It is important that the process for programming data into the memory system be fast so that the host device (or other client) does not have to wait very long for the memory system to finish programming.

### BRIEF DESCRIPTION OF THE DRAWINGS

Like-numbered elements refer to common components in the different FIG.s.

FIG. 1 is a block diagram depicting one embodiment of a memory system.

FIG. 2 is a block diagram of one embodiment of a memory die.

FIG. 3 is a perspective view of a portion of one embodiment of a three dimensional memory structure.

FIG. 4A is a block diagram of a memory structure having two planes.

FIG. 4B depicts a top view of a portion of a block of memory cells.

FIG. 4C depicts a cross sectional view of a portion of a block of memory cells.

FIG. 4D depicts a view of the select gate layers and word line layers.

FIG. 4E is a cross sectional view of a memory hole of memory cells.

FIG. 4F is a schematic of a plurality of NAND strings.

FIG. 5 depicts threshold voltage distributions.

FIG. 6 is a table describing one example of an assignment of data values to data states.

FIG. 7 is a flow chart describing one embodiment of a process for programming non-volatile memory.

FIG. 8A illustrates example voltage sensing waveforms used to determine a data state of a memory cell.

FIG. 8B illustrates example voltage sensing waveforms used to determine a data state of a memory cell.

FIG. 9A depicts a top-down view of an embodiment of a portion of a three-dimensional memory array.

FIG. 9B depicts a top-down view of another embodiment of a portion of a three-dimensional memory array.

FIG. 9C depicts an enlarged view of a portion of the three-dimensional memory array of FIG. 9B.

FIG. 10A depicts a top-down view of still another embodiment of a portion of a three-dimensional memory array.

FIG. 10B depicts a top-down view of yet another embodiment of a portion of a three-dimensional memory array.

FIG. 11 is a flowchart describing an embodiment of a process for performing quarter-bit line voltage sensing.

FIG. 12 depicts a top-down view of the three-dimensional memory array of FIG. 10A.

FIG. 13 depicts a top-down view of a portion of a three-dimensional memory array that includes multiple groups of memory holes and bit lines.

### DETAILED DESCRIPTION

Technology is described for quarter-bit line voltage sensing. In an embodiment, a three-dimensional memory array includes memory holes associated with and coupled to corresponding bit lines. Each memory hole includes one or more memory cells. The memory holes are divided into four segments, with each segment including a subset of the total number of memory holes. The memory holes in each segment are separated from one another by an intervening memory hole from outside the segment.

In an embodiment, selected memory cells in the memory holes are read in four separate read intervals. In each read interval, bit lines associated with memory holes from one of the segments are coupled to sense amplifiers, bit lines associated with memory holes from the other three segments are coupled to GROUND, and the sense amplifiers are used to determine memory states for the selected memory cells in the memory holes in the segment. Without wanting to be bound by any particular theory, it is believed that the quarter-bit line voltage sensing technology described herein may substantially reduce the effects of parasitic capacitive coupling between adjacent memory holes.

In an embodiment, the memory holes include four segments of memory holes, and the memory holes in each segment are separated from one another by an intervening memory hole from outside the segment.

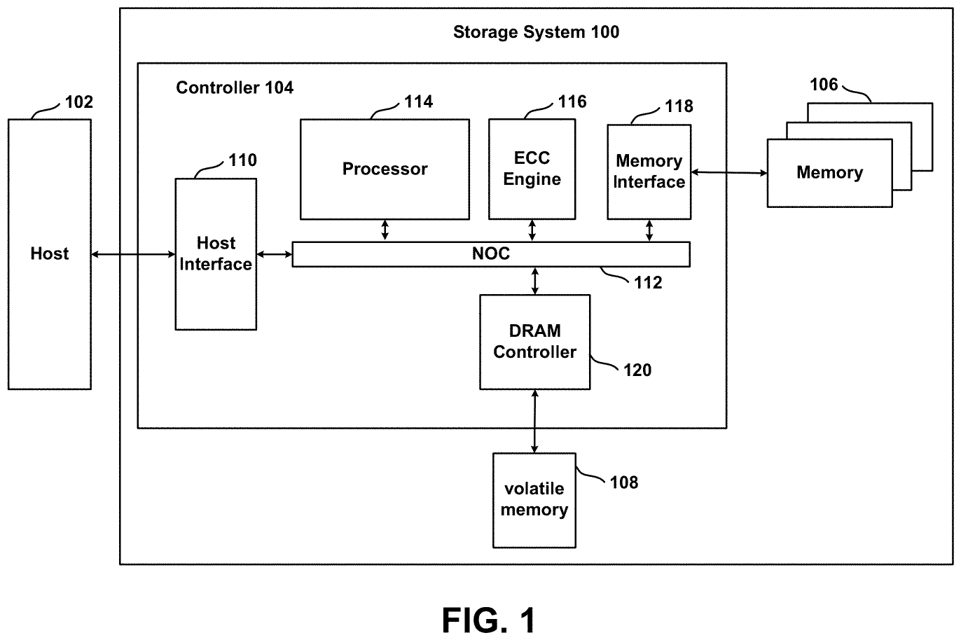

FIG. 1 is a block diagram of an embodiment of a memory system 100 that implements the described technology. In an embodiment, storage system 100 is a solid state drive (“SSD”). Memory system 100 also can be a memory card, USB drive or other type of storage system. The proposed technology is not limited to any one type of memory system. Memory system 100 is connected to host 102, which can be a computer, server, electronic device (e.g., smart phone, tablet or other mobile device), appliance, or another apparatus that uses memory and has data processing capabilities. In some embodiments, host 102 is separate from, but connected to, memory system 100. In other embodiments, memory system 100 is embedded within host 102.

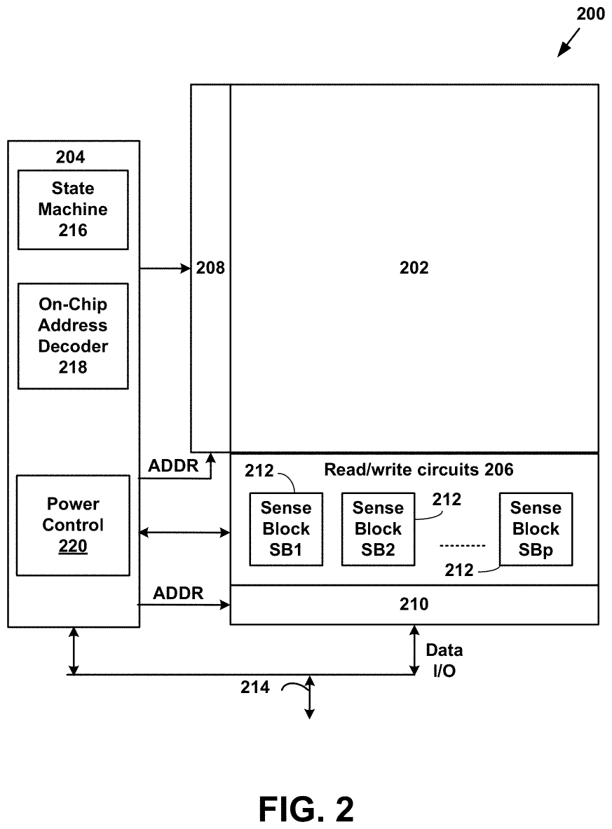

The components of memory system 100 depicted in FIG. 1 are electrical circuits. Memory system 100 includes a controller 104 connected to one or more memory die 106 and local high speed volatile memory 108 (e.g., DRAM). The one or more memory die 106 each include a plurality of non-volatile memory cells. More information about the structure of each memory die 106 is provided below with respect to FIG. 2. Local high speed volatile memory 108 is used by controller 104 to perform certain functions. For example, local high speed volatile memory 108 stores logical to physical address translation tables (“L2P tables”)

Controller 104 includes a host interface 110 that is connected to and in communication with host 102. In one embodiment, host interface 110 provides a PCIe interface. Other interfaces can also be used, such as SCSI, SATA, etc. Host interface 110 is also connected to a network-on-chip (NOC) 112, which is a communication subsystem on an integrated circuit. In other embodiments, NOC 112 can be replaced by a bus.

A NOC can span synchronous and asynchronous clock domains or use unclocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs. In embodiments, the wires and the links of a NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges).

Connected to and in communication with NOC 112 is processor 114, ECC engine 116, memory interface 118, and DRAM controller 120. DRAM controller 120 is used to operate and communicate with local high speed volatile memory 108 (e.g., DRAM). In other embodiments, local high speed volatile memory 108 can be SRAM or another type of volatile memory.

ECC engine 116 performs error correction services. For example, ECC engine 116 performs data encoding and decoding, as per the implemented ECC technique. In one embodiment, ECC engine 116 is an electrical circuit programmed by software. For example, ECC engine 116 can be a processor that can be programmed. In other embodiments, ECC engine 116 is a custom and dedicated hardware circuit without any software. In another embodiment, the function of ECC engine 116 is implemented by processor 114.

Processor 114 performs the various controller memory operations, such as programming, erasing, reading, as well as memory management processes. In an embodiment, processor 114 is programmed by firmware. In other embodiments, processor 114 is a custom and dedicated hardware circuit without any software. In an embodiment, processor 114 also implements a translation module, as a software/firmware process or as a dedicated hardware circuit.

In many systems, non-volatile memory is addressed internally to the storage system using physical addresses associated with the one or more memory die. However, the host system will use logical addresses to address the various memory locations. This enables the host to assign data to consecutive logical addresses, while the storage system is free to store the data as it wishes among the locations of the one or more memory die. To enable this system, the controller (e.g., the translation module) performs address translation between the logical addresses used by the host and the physical addresses used by the memory dies.

One example implementation is to maintain tables (e.g., the L2P tables mentioned above) that identify a translation between logical addresses and physical addresses. An entry in the L2P table may include an identification of a logical address and corresponding physical address. Although logical address to physical address tables (or L2P tables) include the word “tables” they need not literally be tables. Rather, the logical address to physical address tables (or L2P tables) can be any type of data structure. In some examples, the memory space of a storage system is so large that local memory 108 cannot hold all of the L2P tables. In such a case, the entire set of L2P tables are stored in a memory die 106 and a subset of the L2P tables are cached (L2P cache) in the local high speed volatile memory 108.

In an embodiment, memory interface 118 communicates with one or more memory die 106. In an embodiment, memory interface 118 provides a Toggle Mode interface. Other interfaces also can be used. In some example implementations, memory interface 118 (or another portion of controller 104) implements a scheduler and buffer for transmitting data to and receiving data from one or more memory die.

FIG. 2 is a functional block diagram of one embodiment of a memory die 200. Each of the one or more memory die 106 of FIG. 1 can be implemented as memory die 200 of FIG. 2. The components depicted in FIG. 2 are electrical circuits. In an embodiment, each memory die 200 includes a memory structure 202, control circuitry 204, and read/write circuits 206. Memory structure 202 is addressable by word lines via a row decoder 208 and by bit lines via a column decoder 210.

In an embodiment, read/write circuits 206 include multiple sense blocks 212 including SB1, SB2, . . . , SBp (sensing circuitry) and allow a page (or multiple pages) of data in multiple memory cells to be read or programmed (written) in parallel. In an embodiment, each sense block 212 include a sense amplifier and a set of latches connected to the bit line. The latches store data to be written and/or data that has been read. In an embodiment, each sense amplifier 212 includes bit line drivers. In an embodiment, commands and data are transferred between controller 104 (FIG. 1) and memory die 200 via lines 214. In an embodiment, memory die 200 includes a set of input and/or output (I/O) pins that connect to lines 214.

In an embodiment, control circuitry 204 cooperates with read/write circuits 206 to perform memory operations (e.g., write, read, erase, and others) on memory structure 202. In an embodiment, control circuitry 204 includes a state machine 216, an on-chip address decoder 218, and a power control circuit 220. In an embodiment, state machine 216 provides die-level control of memory operations. In an embodiment, state machine 216 is programmable by software. In other embodiments, state machine 216 does not use software and is completely implemented in hardware (e.g., electrical circuits). In some embodiments, state machine 216 can be replaced by a microcontroller or microprocessor. In an embodiment, control circuitry 204 includes buffers such as registers, ROM fuses and other storage devices for storing default values such as base voltages and other parameters.

On-chip address decoder 218 provides an address interface between addresses used by controller 104 (FIG. 1) to the hardware address used by row decoder 208 and column decoder 210. Power control module 220 controls the power and voltages supplied to the word lines and bit lines during memory operations. Power control module 220 may include charge pumps for creating voltages.

For purposes of this document, control circuitry 204, read/write circuits 206, row decoder 208 and column decoder 210 comprise a control circuit for memory structure 202. In other embodiments, other circuits that support and operate on memory structure 202 can be referred to as a control circuit. For example, in some embodiments, controller 104 (FIG. 1) can operate as the control circuit or can be part of the control circuit. The control circuit can also be implemented as a microprocessor or other type of processor that is hardwired or programmed to perform the functions described herein.

For purposes of this document, control circuitry 204, read/write circuits 206, row decoder 208 and column decoder 210 comprise peripheral circuits for memory structure 202, as they are not part of memory structure 202 but are on the same die as memory structure 202 and are used to operate memory structure 202.

In an embodiment, memory structure 202 is a three dimensional memory array of non-volatile memory cells. In an embodiment, memory structure 202 is a monolithic three dimensional memory array in which multiple memory levels are formed above a single substrate, such as a wafer. The memory structure may be any type of non-volatile memory that is formed in one or more physical levels of arrays of memory cells having an active area disposed above a silicon (or other type of) substrate. In one example, the non-volatile memory cells of memory structure 202 include vertical NAND strings with charge-trapping material such as described. A NAND string includes memory cells connected by a channel.

In another embodiment, memory structure 202 includes a two dimensional memory array of non-volatile memory cells. In an example, the non-volatile memory cells are NAND flash memory cells utilizing floating gates. Other types of memory cells (e.g., NOR-type flash memory) also can be used.

The exact type of memory array architecture or memory cell included in memory structure 202 is not limited to the examples above. Many different types of memory array architectures or memory cell technologies can be used to form memory structure 202. No particular non-volatile memory technology is required for purposes of the new claimed embodiments proposed herein.

Other examples of suitable technologies for memory cells of the memory structure 202 include ReRAM memories, magnetoresistive memory (e.g., MRAM, Spin Transfer Torque MRAM, Spin Orbit Torque MRAM), phase change memory (e.g., PCM), and the like. Examples of suitable technologies for architectures of memory structure 202 include two dimensional arrays, three dimensional arrays, cross-point arrays, stacked two dimensional arrays, vertical bit line arrays, and the like.

One example of a ReRAM, or PCMRAM, cross point memory includes reversible resistance-switching elements arranged in cross point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes.

Magnetoresistive memory (MRAM) stores data by magnetic storage elements. The elements are formed from two ferromagnetic plates, each of which can hold a magnetization, separated by a thin insulating layer. One of the two plates is a permanent magnet set to a particular polarity; the other plate's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created.

Phase change memory (PCM) exploits the unique behavior of chalcogenide glass. One embodiment uses a GeTe—Sb₂Te₃ super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light.

A person of ordinary skill in the art will recognize that the technology described herein is not limited to a single specific memory structure, but covers many relevant memory structures within the spirit and scope of the technology as described herein and as understood by one of ordinary skill in the art.

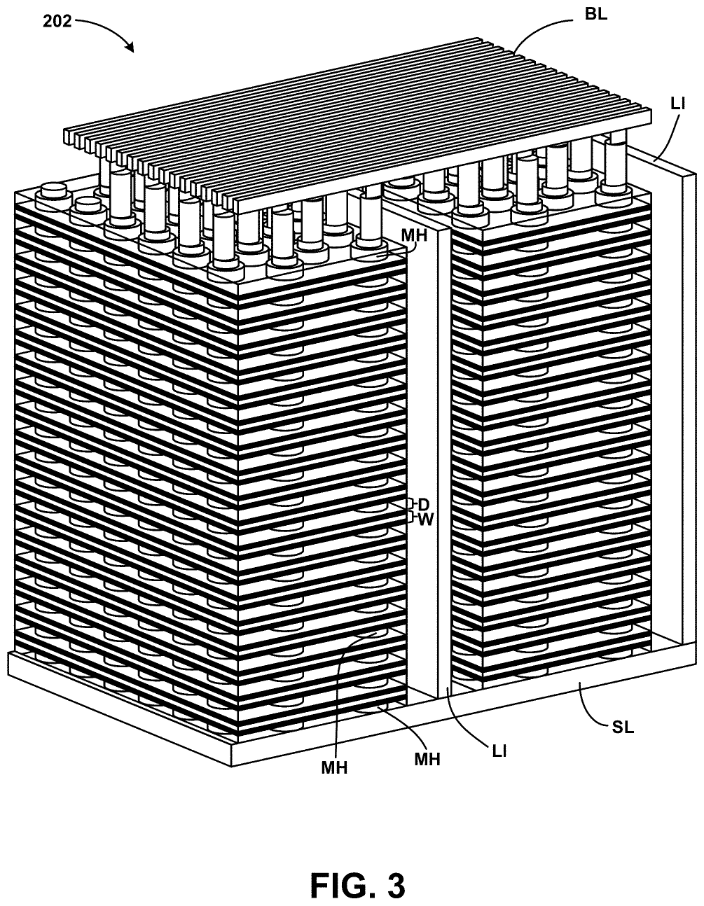

FIG. 3 is a perspective view of a portion of an embodiment of a three dimensional memory array that includes memory structure 202. In an embodiment, memory structure 202 includes multiple non-volatile memory cells. For example, FIG. 3 shows a portion of one block of memory cells. The structure depicted includes a set of bit lines BL positioned above a stack of alternating dielectric layers and conductive layers. For example purposes, one of the dielectric layers is marked as D and one of the conductive layers (also called word line layers) is marked as W.

The number of alternating dielectric layers and conductive layers can vary based on specific implementation requirements. One set of embodiments includes between 108-300 alternating dielectric layers and conductive layers. One example embodiment includes 96 data word line layers, 8 select layers, 6 dummy word line layers and 110 dielectric layers. More or less than 108-300 layers can also be used. As will be explained below, the alternating dielectric layers and conductive layers are divided into four “fingers” by local interconnects LI. FIG. 3 shows two fingers and two local interconnects LI.

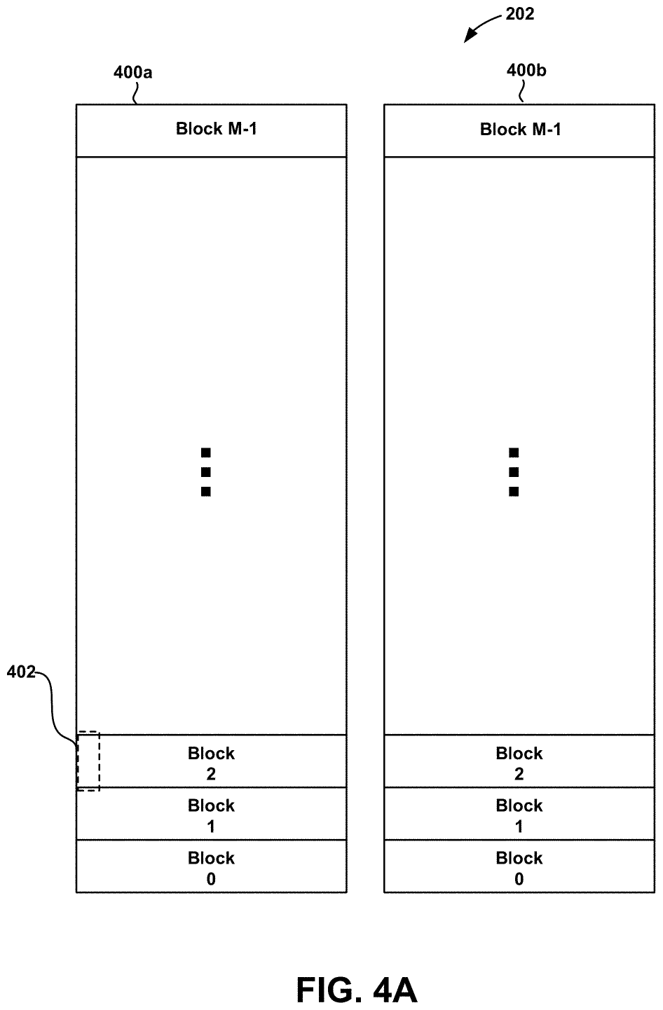

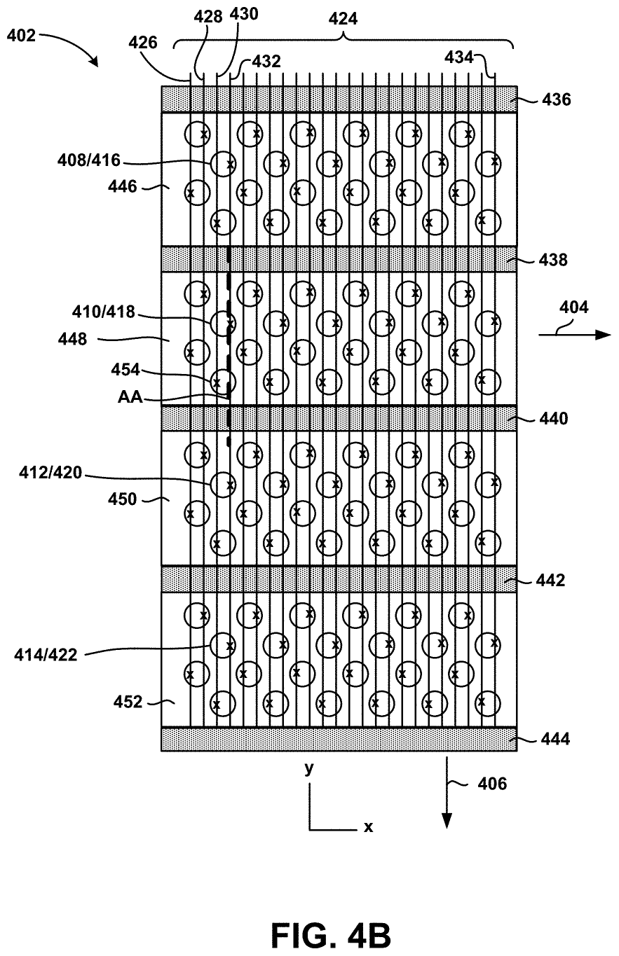

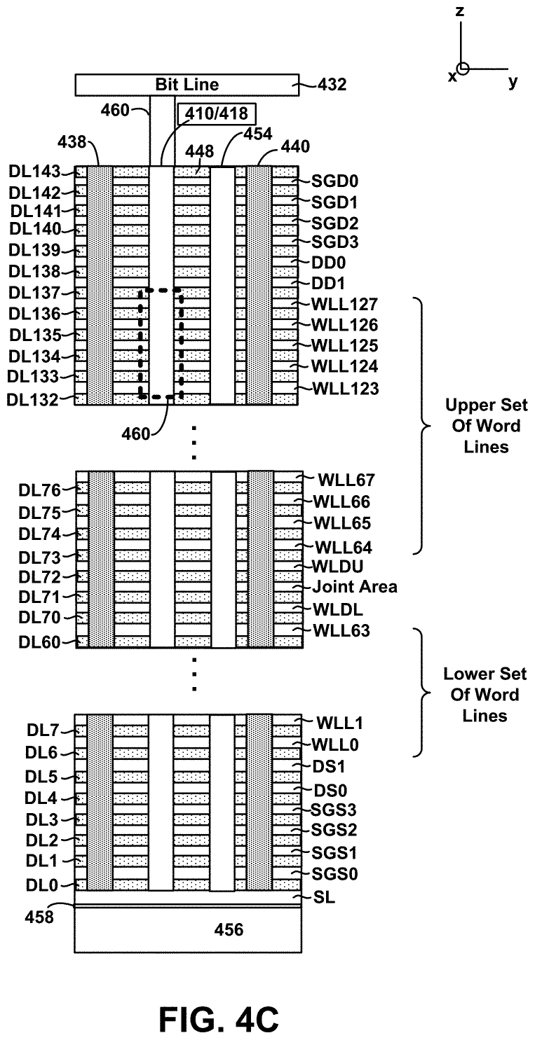

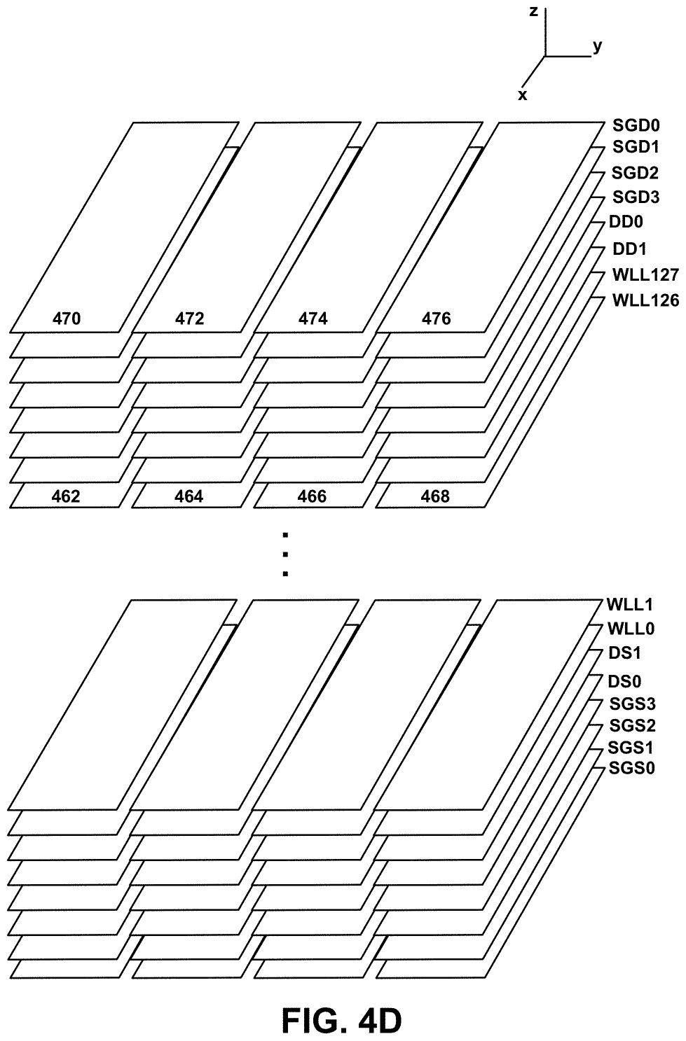

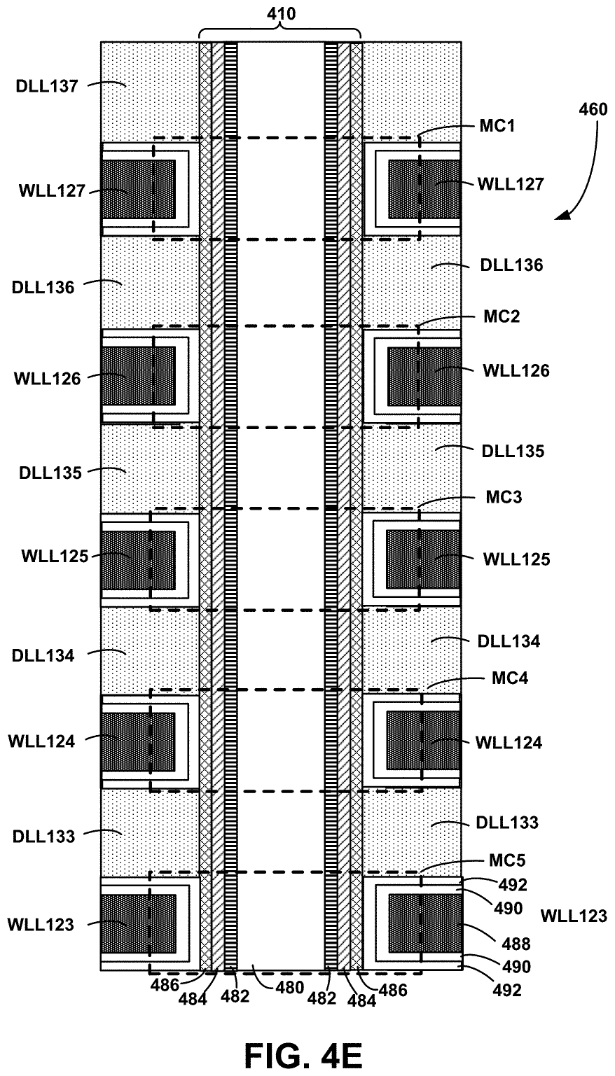

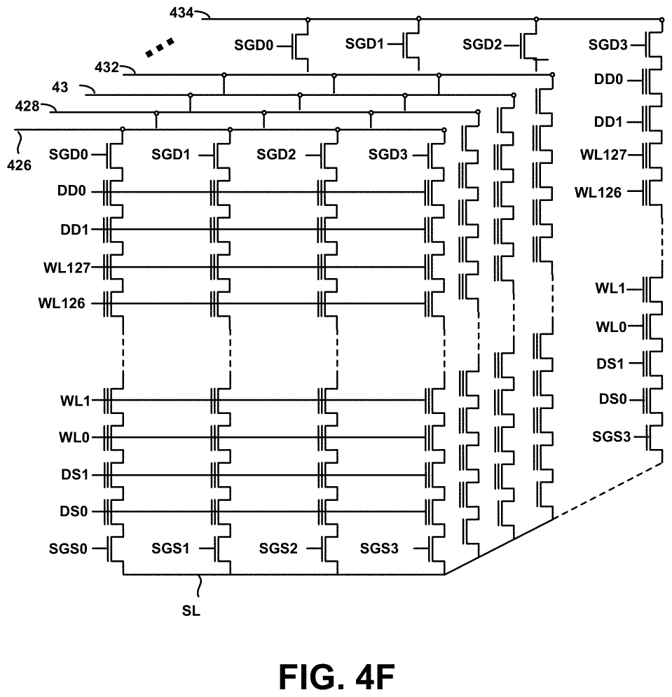

Below the alternating dielectric layers and word line layers is a source line layer SL. Memory holes are formed in the stack of alternating dielectric layers and conductive layers. For example, one of the memory holes is marked as MH. Note that in FIG. 3, the dielectric layers are depicted as see-through so that the reader can see the memory holes positioned in the stack of alternating dielectric layers and conductive layers. In an embodiment, NAND strings are formed by filling the memory hole with materials including a charge-trapping material to create a vertical column of memory cells (also referred to as a memory column). In an embodiment, each memory cell can store one or more bits of data. In an embodiment, each memory hole MH is associated with and coupled to a corresponding one of bit lines BL. In an embodiment, each bit line BL is coupled to one or more memory holes MH. More details of the three dimensional memory array that comprises memory structure 202 is provided below with respect to FIG. 4A-4F.

FIG. 4A is a block diagram explaining one example organization of memory structure 202, which is divided into two planes 400a and 400b. Both planes are on the same memory die 200 (see FIG. 2). Each plane is then divided into M blocks. In one example, each plane has about 2000 blocks. However, different numbers of blocks and planes also can be used. A portion 402 of block 2 of memory plane 400a is shown in dashed line in FIG. 4A.

In an embodiment, a block of memory cells is a unit of erase. That is, all memory cells of a block are erased together. In other embodiments, memory cells can be grouped into blocks for other reasons, such as to organize memory structure 202 to enable the signaling and selection circuits. In some embodiments, a block represents a group of connected memory cells as the memory cells of a block share a common set of word lines. Although FIG. 4A shows two planes on the same die, in other embodiments more than two planes can be implemented. For example, memory structure 202 can include 2-8 (or more) planes.

FIGS. 4B-4F depict an example three dimensional (“3D”) NAND structure that corresponds to the structure of FIG. 3. FIG. 4B is a block diagram depicting a top view of portion 402 (FIG. 4A) of memory structure 202. As can be seen from FIG. 4B, portion 402 extends in direction 404 and direction 406. In an embodiment, the memory array has many layers, however, FIG. 4B only shows the top layer.

FIG. 4B depicts a plurality of circles that represent the memory holes, which are also referred to as memory columns. Each of the memory holes include multiple select transistors (also referred to as a select gate or selection gate) and multiple memory cells. In an embodiment, each memory hole implements a NAND string.

For example, FIG. 4B depicts memory holes 408, 410, 412 and 414. Memory hole 408 implements NAND string 416. Memory hole 410 implements NAND string 418. Memory hole 412 implements NAND string 420. Memory hole 414 implements NAND string 422. More details of the memory holes are provided below. Because portion 402 extends in directions 404 and 406, the block includes more memory holes than depicted in FIG. 4B.

FIG. 4B also depicts a set of bit lines 424, including bit lines 426, 428, 430, 432, . . . 434. In an embodiment, each memory hole is associated with and coupled to a corresponding one of the bit lines. In an embodiment, each bit line is coupled to one or more memory holes. FIG. 4B shows twenty four bit lines because only a portion of the block is depicted. It is contemplated that more than twenty four bit lines connected to memory holes of the block. Each of the circles representing memory holes has an “x” to indicate its connection to one bit line. For example, bit line 432 is connected to memory holes 408, 410, 412 and 414.

Portion 402 depicted in FIG. 4B includes a set of local interconnects 436, 438, 440, 442 and 444 that connect the various layers to a source line below the memory holes. Local interconnects 436, 438, 440, 442 and 444 also serve to divide each layer of the block into four regions. For example, the top layer depicted in FIG. 4B is divided into regions 446, 448, 450 and 452, which are referred to as fingers. In the layers of the block that implement memory cells, regions 446, 448, 450 and 452 are referred to as word line fingers that are separated by the local interconnects.

In an embodiment, the word line fingers on a common level of a block connect together to form a single word line. In another embodiment, the word line fingers on the same level are not connected together. In one example implementation, a bit line only connects to one memory hole in each of regions 446, 448, 450 and 452. In that implementation, each block has sixteen rows of active columns and each bit line connects to four rows in each block.

In an embodiment, all of four rows connected to a common bit line are connected to the same word line (via different word line fingers on the same level that are connected together). Therefore, the system uses the source side selection lines and the drain side selection lines to choose one (or another subset) of the four to be subjected to a memory operation (program, verify, read, and/or erase).

Although FIG. 4B shows each of regions 446, 448, 450 and 452 having four rows of memory holes, four regions and sixteen rows of memory holes in a block, those exact numbers are an example implementation. Other embodiments may include more or less regions per block, more or less rows of memory holes per region and more or less rows of memory holes per block. FIG. 4B also shows the memory holes being staggered. In other embodiments, different patterns of staggering can be used. In some embodiments, the memory holes are not staggered.

FIG. 4C depicts a portion of one embodiment of a three dimensional memory structure 202 showing a cross-sectional view along line AA of FIG. 4B. This cross sectional view cuts through memory holes 410 and 454 and region 448 (see FIG. 4B). The structure of FIG. 4C includes four drain side select layers SGD0, SGD1, SGD2 and SGD3, four source side select layers SGS0, SGS1, SGS2 and SGS3, six dummy word line layers DD0, DD1, DS0, DS1, WLDL, WLDU, and one hundred and twenty eight data word line layers WLL0-WLL127 for connecting to memory cells. Other embodiments can implement more or less than four drain side select layers, more or less than four source side select layers, more or less than six dummy word line layers, and more or less than one hundred and twenty eight word lines.

Memory holes 410 and 454 are depicted protruding through the drain side select layers, source side select layers, dummy word line layers and word line layers. In one embodiment, each memory hole includes a vertical NAND string. For example, memory hole 410 includes NAND string 418. Below the memory holes and the layers listed below is substrate 456, an insulating film 458 on the substrate, and source line SL. The NAND string of memory hole 410 has a source end at a bottom of the stack and a drain end at a top of the stack. As in agreement with FIG. 4B, FIG. 4C show memory hole 410 connected to bit line 432 via connector 460. Local interconnects 438 and 440 are also depicted.

For ease of reference, drain side select layers SGD0, SGD1, SGD2 and SGD3, source side select layers SGS0, SGS1, SGS2 and SGS3, dummy word line layers DD0, DD1, DS0, DS1, WLDL and WLDU, and word line layers WLL0-WLL127 collectively are referred to as the conductive layers. In an embodiment, the conductive layers are made from a combination of TiN and tungsten. In other embodiments, other materials can be used to form the conductive layers, such as doped polysilicon, metal such as tungsten or metal silicide. In some embodiments, different conductive layers can be formed from different materials.

Between conductive layers are dielectric layers DL0-DL143. For example, dielectric layers DL136 is above word line layer WLL126 and below word line layer WLL127. In an embodiment, the dielectric layers are made from SiO₂. In other embodiments, other dielectric materials can be used to form the dielectric layers.

The non-volatile memory cells are formed along memory holes which extend through alternating conductive and dielectric layers in the stack. In an embodiment, the memory cells are arranged in NAND strings. The word line layers WLL0-WLL127 connect to memory cells (also called data memory cells). Dummy word line layers DD0, DD1, DS0, DS1, WLDL and WLDU connect to dummy memory cells. A dummy memory cell does not store and is not eligible to store host data (data provided from the host, such as data from a user of the host), while a data memory cell is eligible to store host data.

In some embodiments, data memory cells and dummy memory cells may have a same structure. A dummy word line is connected to dummy memory cells. Drain side select layers SGD0, SGD1, SGD2 and SGD3 are used to electrically connect and disconnect NAND strings from bit lines. Source side select layers SGS0, SGS1, SGS2 and SGS3 are used to electrically connect and disconnect NAND strings from the source line SL.

FIG. 4C also shows a “Joint Area.” In an embodiment it is expensive and/or challenging to etch one hundred and twenty-eight word line layers intermixed with dielectric layers. To ease this burden, one embodiment includes laying down a first stack of sixty four word line layers alternating with dielectric layers, laying down the Joint Area, and laying down a second stack of sixty four word line layers alternating with dielectric layers. The Joint Area is positioned between the first stack and the second stack. The Joint Area is used to connect the first stack to the second stack.

In FIG. 4C, the first stack is labeled as the “Lower Set of Word Lines” and the second stack is labeled as the “Upper Set of Word Lines.” In an embodiment, the Joint Area is made from the same materials as the word line layers. In one example set of implementations, the plurality of word lines (control lines) comprises a first stack of alternating word line layers and dielectric layers, a second stack of alternating word line layers and dielectric layers, and a joint area between the first stack and the second stack, as depicted in FIG. 4C.

FIG. 4D depicts a logical representation of the conductive layers (SGD0, SGD1, SGD2, SGD3, SGS0, SGS1, SGS2, SGS3, DD0, DD1, DS0, DS1, and WLL0-WLL127) for the block that is partially depicted in FIG. 4C. As mentioned above with respect to FIG. 4B, in an embodiment local interconnects 436, 438, 440, 442 and 444 break up the conductive layers into four regions/fingers. For example, word line layer WLL126 is divided into regions 462, 464, 466 and 468. In an embodiment, the four word line fingers on a same level are connected together. In another embodiment, each word line finger operates as a separate word line. Likewise, drain side select gate layer SGD0 (the top layer) is divided into regions 470, 472, 474 and 476, also known as fingers or select line fingers. In an embodiment, the four select line fingers on a same level are connected together. In another embodiment, each select line finger operates as a separate word line.

FIG. 4E depicts a cross sectional view of region 460 of FIG. 4C that includes a portion of memory hole 410. In an embodiment, the memory holes (e.g., memory hole 410) are shaped as cylinders. In other embodiment, however, memory holes may have other shapes. In an embodiment, memory hole 410 includes an inner core layer 480, a channel 482 surrounding inner core layer 480, a tunneling dielectric 484 surrounding channel 482, and a charge trapping layer 486 surrounding tunneling dielectric 484. In an embodiment, inner core layer 480 a dielectric material (e.g., SiO₂), channel 482 is polysilicon, tunneling dielectric 484 has an ONO structure, and charge trapping layer 486 is silicon nitride. Other memory materials and structures can also be used. The technology described herein is not limited to any particular material or structure.

FIG. 4E depicts dielectric layers DLL137, DLL136, DLL135, DLL134 and DLL133, as well as word line layers WLL127, WLL126, WLL125, WLL124, and WLL123. In an embodiment, each of the word line layers includes a word line region 488 surrounded by an aluminum oxide layer 490, which is surrounded by a blocking oxide (SiO₂) layer 492. The physical interaction of the word line layers with the memory hole forms the memory cells. Thus, a memory cell, in an embodiment, includes channel 482, tunneling dielectric 484, charge trapping layer 486, blocking oxide layer 492, aluminum oxide layer 490 and word line region 488.

For example, word line layer WLL127 and a portion of memory hole 410 comprise a memory cell MC1. Word line layer WLL126 and a portion of memory hole 410 comprise a memory cell MC2. Word line layer WLL125 and a portion of memory hole 410 comprise a memory cell MC3. Word line layer WLL124 and a portion of memory hole 410 comprise a memory cell MC4. Word line layer WLL123 and a portion of memory hole 410 comprise a memory cell MC5. In other architectures, a memory cell may have a different structure; however, the memory cell would still be the storage unit.

In an embodiment, when a memory cell is programmed, electrons are stored in a portion of the charge trapping layer 486 which is associated with the memory cell. These electrons are drawn into the charge trapping layer 486 from the channel 482, through the tunneling dielectric 484, in response to an appropriate voltage on word line region 488. The threshold voltage (Vth) of a memory cell is increased in proportion to the amount of stored charge.

In an embodiment, programming a memory cell is achieved through Fowler-Nordheim tunneling of the electrons into charge trapping layer 486. During an erase operation, the electrons return to channel 482 or holes are injected into charge trapping layer 486 to recombine with electrons. In an embodiment, erasing is achieved using hole injection into charge trapping layer 486 via a physical mechanism such as gate induced drain leakage (GIDL).

FIG. 4F is a schematic diagram of corresponding to portion 402 in Block 2 of FIGS. 4A-E, including bit lines 426, 428, 430, 432, . . . 434, and word lines WLL0-WLL127. Within the block, each bit line is connected to four NAND strings. Drain side selection lines SGD0, SGD1, SGD2 and SGD3 are used to determine which of the four NAND strings connect to the associated bit line(s). Source side selection lines SGS0, SGS1, SGS2 and SGS3 are used to determine which of the four NAND strings connect to the common source line.

During any given memory operation, a subset of the memory cells will be identified to be subjected to one or more parts of the memory operation. These memory cells identified to be subjected to the memory operation are referred to as selected memory cells. Memory cells that have not been identified to be subjected to the memory operation are referred to as unselected memory cells. Depending on the memory architecture, the memory type, and the memory operation, unselected memory cells may be actively or passively excluded from being subjected to the memory operation.

During a memory operation some word lines are referred to as selected word lines because they are connected to selected memory cells. Unselected word lines are not connected to selected memory cells. Similarly, selected bit lines are connected to selected memory cells and unselected bit lines are not connected to selected memory cells.

Although the example memory system of FIGS. 3-4F is a three dimensional memory structure that includes vertical NAND strings with charge-trapping material, other (2D and 3D) memory structures also can be used with the technology described herein.

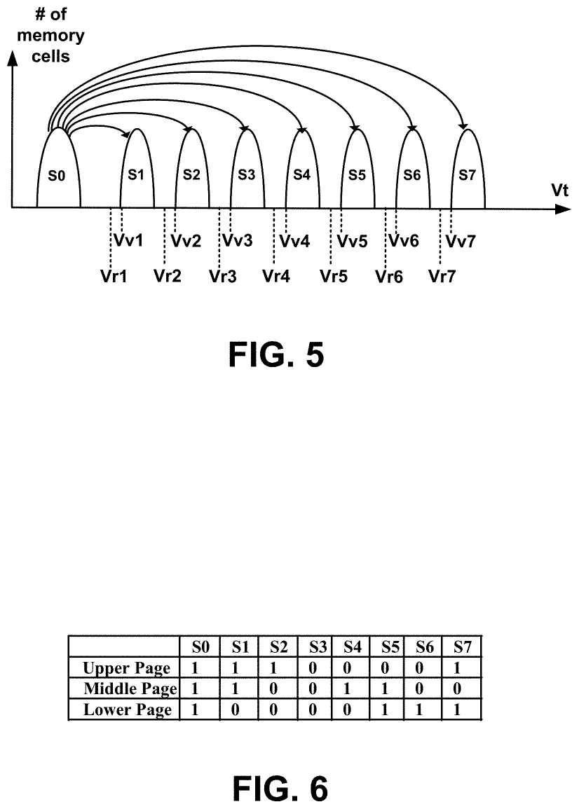

The memory systems discussed above can be erased, programmed and read. At the end of a successful programming process (with verification), the threshold voltages of the memory cells should be within one or more distributions of threshold voltages for programmed memory cells or within a distribution of threshold voltages for erased memory cells, as appropriate. FIG. 5 illustrates example threshold voltage distributions for a memory array when each memory cell stores three bits of data. Other embodiments, however, may use other data capacities per memory cell (e.g., such as one, two, four, or five bits of data per memory cell).

FIG. 5 shows eight threshold voltage distributions, corresponding to eight data states. The first threshold voltage distribution (data state) S0 represents memory cells that are erased. The other seven threshold voltage distributions (data states) S1-S17 represent memory cells that are programmed and, therefore, are also called programmed states. Each threshold voltage distribution (data state) corresponds to predetermined values for the set of data bits. The specific relationship between the data programmed into a memory cell and the threshold voltage levels of the memory cell depends upon the data encoding scheme adopted for the cells. In an embodiment, data values are assigned to the threshold voltage ranges using a Gray code assignment so that if the threshold voltage of a memory cell erroneously shifts to its neighboring physical state, only one bit will be affected.

FIG. 5 shows seven read reference voltages, Vr1, Vr2, Vr3, Vr4, Vr5, Vr6, and Vr7 for reading data from memory cells. By testing (e.g., performing sense operations) whether the threshold voltage of a given memory cell is above or below the seven read reference voltages, the system can determine what data state (S0, S1, S2, S3, . . . , S7) a memory cell is in.

FIG. 5 also shows seven verify reference voltages, Vv1, Vv2, Vv3, Vv4, Vv5, Vv6, and Vv7. When programming memory cells to data state S1, the system will test whether those memory cells have a threshold voltage greater than or equal to Vv1. When programming memory cells to data state S2, the system will test whether the memory cells have threshold voltages greater than or equal to Vv2. When programming memory cells to data state S3, the system will determine whether memory cells have their threshold voltage greater than or equal to Vv3. When programming memory cells to data state S4, the system will test whether those memory cells have a threshold voltage greater than or equal to Vv4. When programming memory cells to data state S5, the system will test whether those memory cells have a threshold voltage greater than or equal to Vv5. When programming memory cells to data state S6, the system will test whether those memory cells have a threshold voltage greater than or equal to Vv6. When programming memory cells to data state S7, the system will test whether those memory cells have a threshold voltage greater than or equal to Vv7.

In an embodiment, known as full sequence programming, memory cells can be programmed from the erased data state S0 directly to any of the programmed data states S1-S7. For example, a population of memory cells to be programmed may first be erased so that all memory cells in the population are in erased data state S0. Then, a programming process is used to program memory cells directly into data states S1, S2, S3, S4, S5, S6, and/or S7. For example, while some memory cells are being programmed from data state S0 to data state S1, other memory cells are being programmed from data state S0 to data state S2 and/or from data state S0 to data state S3, and so on. The arrows of FIG. 5 represent full sequence programming. The technology described herein can also be used with other types of programming in addition to full sequence programming (including, but not limited to, multiple stage/phase programming). In some embodiments, data states S1-S7 can overlap, with controller 104 (FIG. 1) relying on error correction to identify the correct data being stored.

FIG. 6 is a table describing an example assignment of data values to data states. In the table of FIGS. 6, S0=111. S1=110, S2=100, S3=000, S4=010, S5=011, S6=001 and S7=101. Other encodings of data also can be used. No particular data encoding is required by the technology disclosed herein. In an embodiment, when a block is subjected to an erase operation, all memory cells are moved to data state S0, the erased state. In the embodiment of FIG. 6, all bits stored in a memory cell are 1 when the memory cell is erased (e.g., in data state S0).

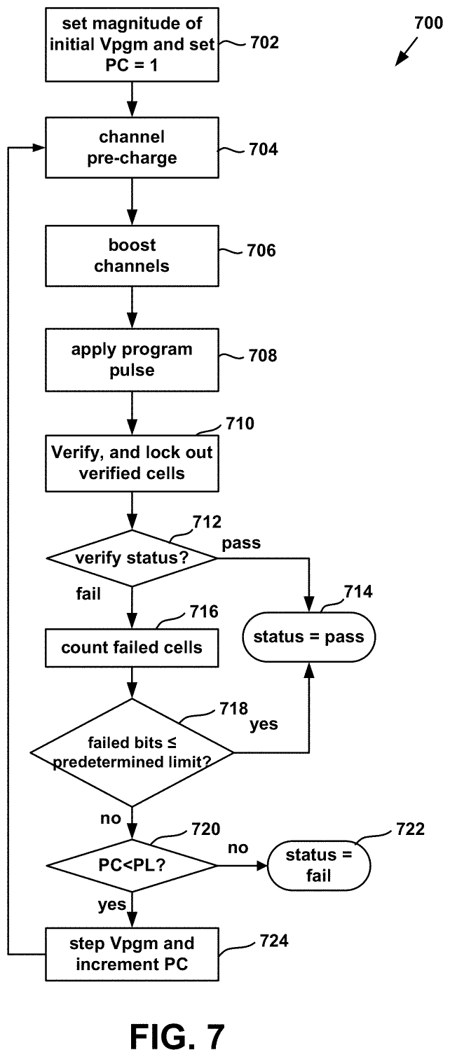

FIG. 7 is a flowchart describing an embodiment of a process 700 for programming a memory cell. In one example embodiment, process 700 is performed on memory die 106 (FIG. 1) using the control circuit discussed above. For example, process 700 can be performed at the direction of state machine 216 (FIG. 2). Process 700 also can be used to implement the full sequence programming discussed above. Additionally, process 700 can be used to implement each phase of a multi-phase programming process.

Typically, the program voltage applied to the control gates (via a selected word line) during a program operation is applied as a series of program pulses. Between programming pulses are a set of verify pulses to perform verification. In many implementations, the magnitude of the program pulses is increased with each successive pulse by a predetermined step size. In step 702 of FIG. 7, the programming voltage (Vpgm) is initialized to the starting magnitude (e.g., ˜12-16V or another suitable level) and a program counter PC maintained by state machine 216 is initialized at 1.

In an embodiment, the group of memory cells in a same block that are selected to be programmed (referred to herein as the selected memory cells) are programmed concurrently and are all connected to the same word line (the selected word line). There will likely be other memory cells that are not selected for programming (unselected memory cells) that are also connected to the selected word line. That is, the selected word line will also be connected to memory cells that are supposed to be inhibited from programming.

For example, when data are written to a set of memory cells, some of the memory cells will need to store data associated with state S0, and thus such memory cells will not be programmed. Additionally, as memory cells reach their intended target data state, such memory cells will be inhibited from further programming. Those NAND strings that include memory cells connected to the selected word line that are to be inhibited from programming have their channels boosted to inhibit programming. When a channel has a boosted voltage, the voltage differential between the channel and the word line is not large enough to cause programming.

To assist in the boosting, in step 704 the memory system will pre-charge channels of NAND strings that include memory cells connected to the selected word line that are to be inhibited from programming. In some embodiments, only the drain side of the channel is pre-charged. By “drain side” it is meant the portion of the NAND string on the same side of the selected word line as the bit line connection.

In step 706, NAND strings that include memory cells connected to the selected word line that are to be inhibited from programming have their channels boosted to inhibit programming. In one embodiment, the unselected word lines receive one or more boosting voltages (e.g., ˜7-11 volts) to perform boosting schemes known in the art.

In step 708, a program pulse of the program signal Vpgm is applied to the selected word line (the word line selected for programming). If a memory cell should be programmed, then the corresponding bit line is grounded. On the other hand, if the memory cell should remain at its current threshold voltage, then the corresponding bit line is connected to Vdd to inhibit programming.

In step 708, the program pulse is applied to all memory cells connected to the selected word line so that all of the memory cells connected to the selected word line are programmed concurrently. That is, they are programmed at the same time or during overlapping times (both of which are considered concurrent). In this manner all of the memory cells connected to the selected word line will concurrently have their threshold voltage change, unless they have been locked out from programming.

In step 710, the appropriate memory cells are verified using the appropriate set of verify reference voltages to perform one or more verify operations. In an embodiment, the verification process is performed by testing whether the threshold voltages of the memory cells selected for programming have reached the appropriate verify reference voltage.

In step 712, it is determined whether all the memory cells have reached their target threshold voltages (pass). If so, the programming process is complete and successful because all selected memory cells were programmed and verified to their target states. A status of “PASS” is reported in step 714. If, in step 712, it is determined that not all of the memory cells have reached their target threshold voltages (fail), then the programming process continues to step 716.

In step 716, the memory system counts the number of memory cells that have not yet reached their respective target threshold voltage distribution. That is, the system counts the number of memory cells that have, so far failed the verify process. This counting can be done by state machine 216 (FIG. 2), controller 104 (FIG. 1), or other logic. In an embodiment, each of sense blocks 212 (FIG. 2) will store the status (pass/fail) of their respective memory cells. In an embodiment, there is one total count, which reflects the total number of memory cells currently being programmed that have failed the last verify step. In another embodiment, separate counts are kept for each data state.

In step 718, it is determined whether the count from step 716 is less than or equal to a predetermined limit. In an embodiment, the predetermined limit is the number of bits that can be corrected by error correction codes (ECC) during a read process for the page of memory cells. If the number of failed cells is less than or equal to the predetermined limit, than the programming process can stop and a status of “PASS” is reported in step 714. In this situation, enough memory cells programmed correctly such that the few remaining memory cells that have not been completely programmed can be corrected using ECC during the read process.

In some embodiments, the predetermined limit used in step 718 is below the number of bits that can be corrected by error correction codes (ECC) during a read process to allows for future/additional errors. When programming less than all of the memory cells for a page, or comparing a count for only one data state (or less than all states), then the predetermined limit can be a portion (pro-rata or not pro-rata) of the number of bits that can be corrected by ECC during a read process for the page of memory cells. In some embodiments, the limit is not predetermined. Instead, it changes based on the number of errors already counted for the page, the number of program-erase cycles performed or other criteria.

If number of failed memory cells is not less than the predetermined limit, than the programming process continues at step 720 and the program counter PC is checked against the program limit value (PL). Examples of program limit values include 6, 12, 16, 20 and 30, although other values can be used. If the program counter PC is not less than the program limit value PL, then the program process is considered to have failed and a status of FAIL is reported in step 722.

If the program counter PC is less than the program limit value PL, then the process continues at step 724 in which the Program Counter PC is incremented by 1 and the program voltage Vpgm is stepped up to the next magnitude. For example, the next pulse will have a magnitude greater than the previous pulse by a step size (e.g., a step size of 0.1-0.4 volts). After step 724, the process loops back to step 704 and another program pulse is applied to the selected word line so that another iteration (steps 704-724) of programming process 700 is performed.

In general, during verify operations and read operations, the selected word line is connected to a voltage (one example of a reference signal), a level of which is specified for each read operation (e.g., read compare levels Vr1, Vr2, Vr3, Vr4, Vr5, Vr6, and Vr7, of FIG. 5) or verify operation (e.g. verify target levels Vv1, Vv2, Vv3, Vv4, Vv5, Vv6, and Vv7 of FIG. 5) to determine whether a threshold voltage of the selected memory cell has reached such level.

In an embodiment, after an appropriate read or verify voltage is applied to a selected word line, a conduction current of the memory cell is measured to determine whether the memory cell turned ON (conducts current) in response to the voltage applied to the word line. If the conduction current is measured to be greater than a certain value, then it is assumed that the memory cell turned ON and the voltage applied to the word line is greater than the threshold voltage of the memory cell.

If the conduction current is measured to be not greater than the certain value, then the memory cell did not turn ON, and the voltage applied to the word line is not greater than the threshold voltage of the memory cell. During a read or verify process, the unselected memory cells are provided with one or more read pass voltages (also referred to as bypass voltages) at their control gates so that these memory cells will operate as pass gates (e.g., conducting current regardless of whether they are programmed or erased).

There are many ways to measure the conduction state (conductive or non-conductive) of a memory cell during a read or verify operation. In a current sensing technique, the bit line coupled to the selected memory cell is coupled to a pre-charged capacitor in a current sensing module. If the selected memory cell is in a conductive state, the pre-charged capacitor discharges through the bit line and the NAND string into the source line. In contrast, if the selected memory cell is in a non-conductive state, the pre-charged capacitor does not appreciably discharge.

After a predetermined time period, the capacitor voltage is compared to one or more predetermined reference voltages to determine the conductive state of the selected memory cell. For example, for a memory cell that stores one bit of data, if the capacitor voltage is greater than a predetermined reference voltage, the memory cell is deemed to be non-conducting (e.g., OFF). Alternatively, if the capacitor voltage is less than the predetermined reference voltage, the memory cell is deemed to be conducting (e.g., ON).

Voltage sensing, in contrast, does not involve sensing a voltage drop which is tied to a fixed current. Instead, voltage sensing involves determining whether charge sharing occurs between a capacitor in a voltage sensing module (the “sensing capacitor”) and a capacitance of the bit line. In an example embodiment, charge sharing occurs when the selected memory cell is conductive (e.g., ON), in which case the voltage of the sensing capacitor drops significantly. In contrast, little or no charge sharing occurs when the selected memory cell is non-conductive (e.g., OFF), in which case the voltage of the sensing capacitor does not drop significantly.

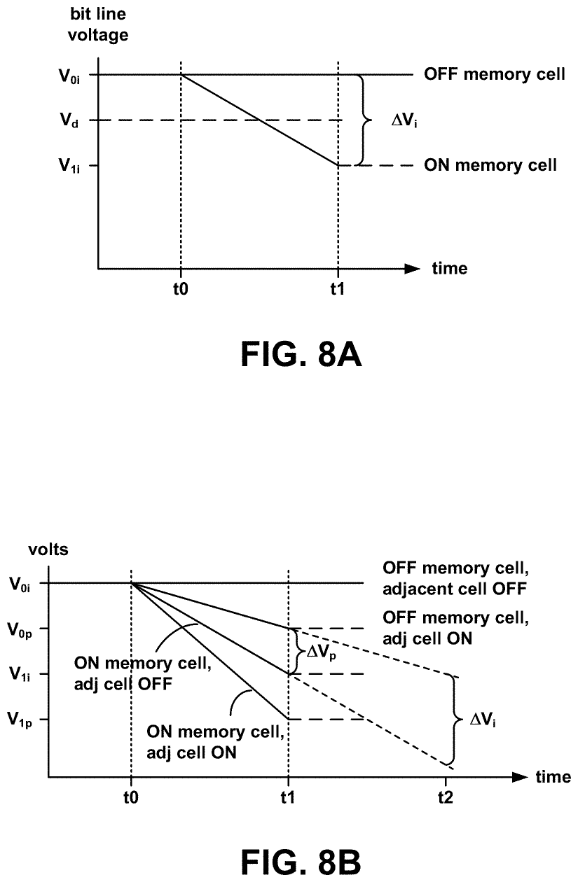

For example, FIG. 8A illustrates example voltage sensing waveforms used to determine a data state of a memory cell. In particular, prior to time t0, the voltage of the bit line is pre-charged to V₀ᵢ. At time t0, the bit line coupled to the selected memory cell is coupled to the sensing capacitor. If the selected memory cell is non-conductive (e.g., OFF), the voltage of the bit line does not drop significantly, and at a sense time t1 the voltage of the sensing capacitor remains at about V₀ᵢ. In contrast, if the selected memory cell is conductive (e.g., ON), the voltage of the sensing capacitor drops significantly with time. At sense time t1, the voltage of the sensing capacitor is V₁ᵢ, which is below decision point V_{d}. If the voltage of the bit line is above V_{d}, charge-sharing between the sensing capacitor and the bit line does not happen, and the voltage of the sensing capacitor remains high. If the voltage of the bit line is below V_{d}, charge-sharing happens and the voltage across the sensing capacitor is small. The voltage difference of bit lines at sense time t1, ΔVᵢ=V₀ᵢ−V₁ᵢ, provides margin for distinguishing between an OFF and an ON memory cell.

As described above, in connection with FIG. 3, an embodiment of a three-dimensional memory array includes an array of memory holes formed in a stack of alternating dielectric layers and conductive layers. As also described above, in an embodiment, NAND strings are formed by filling the memory holes with materials including a charge-trapping material to create a memory hole of memory cells.

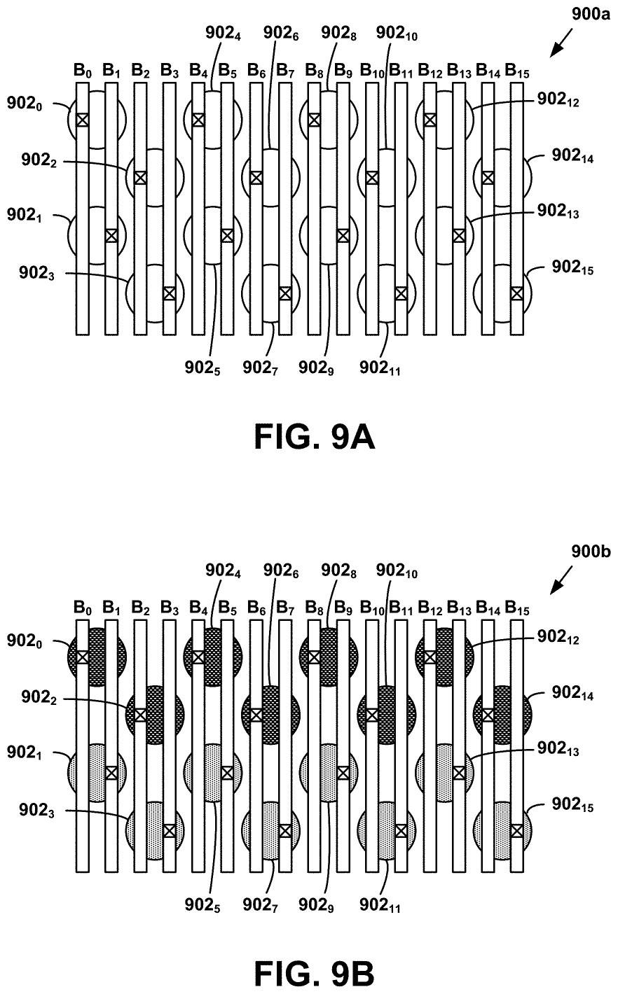

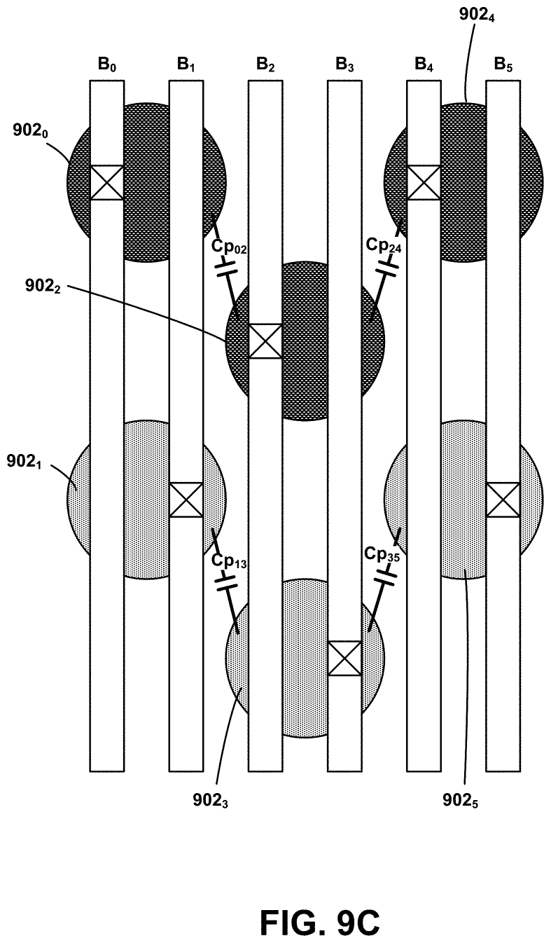

FIG. 9A depicts a top-down view of an embodiment of a portion of a three-dimensional memory array that includes a group 900a of sixteen bit lines B₀, B₁, B₂, . . . B₁₅ and sixteen memory holes 902₀, 902₁, 902₂, . . . , 902₁₅, each including a NAND string of memory cells. Persons of ordinary skill in the art will understand that three-dimensional memory arrays may include more than one group, and each group may include more or fewer than sixteen bit lines, and more or fewer than sixteen memory holes.

In an embodiment, each of memory holes 902₀, 902₁, 902₂, . . . , 902₁₅ is associated with and coupled to a corresponding one of bit lines B₀, B₁, B₂, . . . B₁₅. Although not shown in FIG. 9A, in an embodiment each of bit lines B₀, B₁, B₂, . . . B₁₅ is coupled to one or more memory holes. Each of memory holes 902₀, 902₁, 902₂, . . . , 902₁₅ has an “x” to indicate its connection to a corresponding one of bit lines B₀, B₁, B₂, . . . B₁₅. In particular, each of bit lines B₀, B₁, B₂, . . . B₁₅ is connected to memory holes 902₀, 902₁, 902₂, . . . , 902₁₅, respectively.

In some embodiments, each bit line B₀, B₁, B₂, . . . B₁₅ is coupled to a corresponding sense amplifier used to sense current (for current sensing) or voltage (for voltage sensing) to determine the conductivity state of a selected memory cell in the corresponding memory hole 902₀, 902₁, 902₂, . . . , 902₁₅ coupled to the bit line. For example, each bit line B₀, B₁, B₂, . . . B₁₅ is coupled to a corresponding one of sixteen sense amplifiers.

As a result of parasitic capacitive coupling between adjacent bit lines B₀, B₁, B₂, . . . B₁₅, the bit line settling time t_{BL} for such memory arrays may be unnecessarily long to meet desired memory device specifications. For example, some memory devices require read times t_{R} of 300 nsec or less. Achieving such short read times t_{R} may require a bit line settling time t_{BL} be about 100 nsec or less.

One technique to reduce the effects of parasitic capacitive coupling between adjacent bit lines B₀, B₁, B₂, . . . B₁₅ is (and hence reduce bit line settling time t_{BL}) is sometimes referred to as “half-bit line (HBL) shielded voltage sensing.” For example, FIG. 9B depicts a top-down view of an embodiment of a portion of a three-dimensional memory array that includes a group 900b of sixteen bit lines B₀, B₁, B₂, . . . B₁₅ and sixteen memory holes 902₀, 902₁, 902₂, . . . , 902₁₅, each including a NAND string of memory cells, with bit lines B₀, B₁, B₂, . . . B₁₅ (and corresponding memory holes 902₀, 902₁, 902₂, . . . , 902₁₅) divided into two segments. In particular, bit lines B₀, B₂, B₄, B₆, B₈, B₁₀, B₁₂ and B₁₄ are classified as “even” bit lines, and bit lines B₁, B₃, B₅, B₇, B₉, B₁₁, B₁₃ and B₁₅ are classified as “odd” bit lines.

In an embodiment of HBL shielded voltage sensing, in a first (even) read interval, each of even bit lines B₀, B₂, B₄, B₆, B₈, B₁₀, B₁₂ and B₁₄ is coupled to a corresponding one of eight sense amplifiers, while odd bit lines B₁, B₃, B₅, B₇, B₉, B₁₁, B₁₃ and B₁₅ are coupled to GROUND (or some other predetermined voltage), and the selected memory cells in even memory holes 902₀, 902₂, 902₄, 902₆, 902₈, 902₁₀, 902₁₂ and 902₁₄ are read. Then, in a second (odd) read interval, each of odd bit lines B₁, B₃, B₅, B₇, B₉, B₁₁, B₁₃ and B₁₅ is coupled to a corresponding one of the eight sense amplifiers, while even bit lines B₀, B₂, B₄, B₆, B₈, B₁₀, B₁₂ and B₁₄ are coupled to GROUND (or some other predetermined voltage), and the selected memory cells in odd memory holes 902₁, 902₃, 902₅, 902₇, 902₉, 902₁₁, 902₁₃ and 902₁₅ are read.

Although HBL shielded voltage sensing reduces the effects of parasitic capacitive coupling between adjacent bit lines B₀, B₁, B₂, . . . B₁₅, the technique does not reduce the effects of parasitic capacitive coupling between adjacent selected memory holes 902₀, 902₁, 902₂, . . . , 902₁₅. For example, FIG. 9C depicts an enlarged view of group 900b of FIG. 9B. In particular, parasitic capacitance between adjacent memory holes 902₀ and 902₂ is represented as Cp₀₂, parasitic capacitance between adjacent memory holes 902₂ and 902₄ is represented as Cp₂₄, parasitic capacitance between adjacent memory holes 902₁ and 902₃ is represented as Cp₁₃, and parasitic capacitance between adjacent memory holes 902₃ and 902₅ is represented as Cp₃₅.

During an even read interval, parasitic capacitance Cp₀₂ between adjacent selected memory holes 902₀ and 902₂ and parasitic capacitance Cp₂₄ between adjacent selected memory holes 902₂ and 902₄ may slow the bit line settling time t_{BL} of bit lines B₀, B₂ and B₄, even though the HBL shielded voltage sensing technique shields bit lines B₀ and B₂ from intermediate bit line B₁, and shields bit lines B₂ and B₄ from intermediate bit line B₂. Likewise, during an odd read interval, parasitic capacitance Cp13 between adjacent selected memory holes 902₁ and 902₃ and parasitic capacitance Cp₃₅ between adjacent selected memory holes 902₃ and 902₅ may slow the bit line settling time t_{BL} of bit lines B₁, B₃ and B₅, even though the HBL shielded voltage sensing technique shields bit lines B₁ and B₃ from intermediate bit line B₂, and shields bit lines B₃ and B₅ from intermediate bit line B₄.

FIG. 8B illustrates example voltage sensing waveforms used to determine a data state of a memory cell, including the effects of parasitic capacitance between adjacent selected memory holes. For example, assume that the selected memory cell is a memory cell in memory hole 902₀ in FIG. 9C, and is adjacent a memory cell (the “adjacent memory cell”) in adjacent selected memory hole 902₂.

Prior to time t0, the voltage of the bit line is V₀ᵢ. At time t0, the bit line coupled to the selected memory cell is coupled to the sensing capacitor. If the selected memory cell is non-conductive (e.g., OFF), and the adjacent memory cell is OFF, the voltage of the sensing capacitor does not drop significantly, and at sense time t1 the voltage of the sensing capacitor remains at about V₀ᵢ. However, if the selected memory cell is non-conductive (e.g., OFF), and the adjacent memory cell is ON, as a result of parasitic capacitance Cp₀₂ between adjacent memory holes 902₀ and 902₂, the voltage of the sensing capacitor drops with time. For example, at sense time t1, the voltage of the sense capacitor is V₀ₚ.

If the selected memory cell is conductive (e.g., ON), and the adjacent memory cell is OFF, the voltage of the sensing capacitor drops with time. For example, at sense time t1, the voltage of the sense capacitor is V₁ᵢ. However, if the selected memory cell is conductive (e.g., ON), and the adjacent memory cell is ON, the voltage of the sensing capacitor drops even more with time. For example, at sense time t1, the voltage of the sense capacitor is V₁ₚ.

In this example, the “worst case” voltage difference at sense time t1 is equal to ΔVₚ=V₀ₚ−V₁ᵢ, which provides less margin for distinguishing between OFF and ON memory states than in the example of FIG. 8A, in which the voltage difference at sense time t1 is ΔVᵢ=V₀ᵢ−V₁ᵢ is a minimum voltage margin required to achieve a desired bit error rate, the sense time would need to be extended to time t2 in the “worst case” scenario depicted in FIG. 8B to achieve the same minimum voltage margin ΔVᵢ. The additional time required to achieve the voltage margin ΔVᵢ, however, may exceed the bit line settling time t_{BL} necessary to achieve a required require read time t_{R}. Thus, HBL shielded voltage sensing may not sufficiently reduce the effects of parasitic capacitance between adjacent memory holes.

Technology is described for quarter-bit line (QBL) voltage sensing.” In an embodiment, an apparatus is provided that includes a plurality of non-volatile memory cells, a plurality of bit lines, a plurality of memory holes, and a control circuit. In an embodiment, the memory holes include four segments of memory holes, and the memory holes in each segment are separated from one another by an intervening memory hole from outside the segment. The plurality of memory holes each include a corresponding one of the memory cells. Each memory hole is associated with and coupled to a corresponding one of the bit lines. The control circuit is configured to read the memory cells in four separate read intervals. In an embodiment, the memory holes include four segments of memory holes, and the memory holes in each segment are separated from one another by an intervening memory hole from outside the segment. Without wanting to be bound by any particular theory, it is believed that the QBL voltage sensing technology described herein may substantially reduce the effects of parasitic capacitive coupling between adjacent selected memory holes.

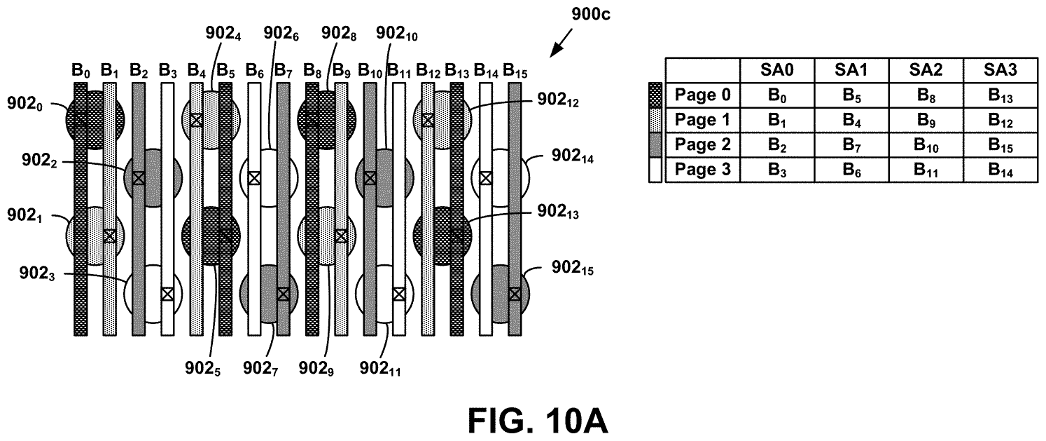

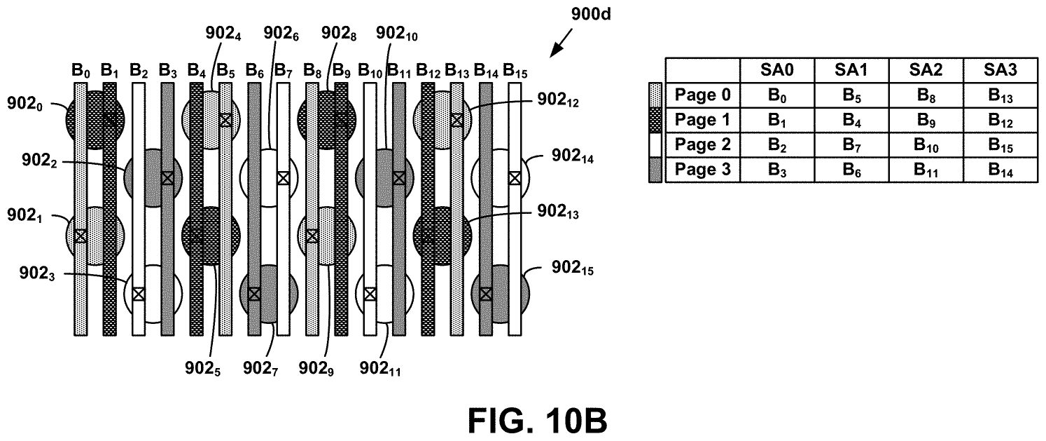

FIG. 10A depicts a top-down view of an embodiment of a portion of a three-dimensional memory array that includes a group 900c of sixteen bit lines B₀, B₁, B₂, . . . , B₁₅ and sixteen memory holes 902₀, 902₁, 902₂, . . . , 902₁₅, each including a NAND string of memory cells. In an embodiment, each of memory holes 902₀, 902₁, 902₂, . . . , 902₁₅ is associated with and coupled to a corresponding one of bit lines B₀, B₁, B₂, . . . B₁₅. Bit lines B₀, B₁, B₂, . . . , B₁₅, (and associated and memory holes 902₀, 902₁, 902₂, . . . , 902₁₅) are conceptually divided into four segments. In particular, bit lines B₀, B₅, B₈ and B₁₃ are classified herein as “first quarter bit lines,” bit lines B₁, B₄, B₉ and B₁₂ are classified herein as “second quarter bit lines,” bit lines B₂, B₇, B₁₀ and B₁₅ are classified herein as “third quarter bit lines,” and bit lines B₃, B₆, B₁₁ and B₁₄ are classified herein as “fourth quarter bit lines.”

Similarly, memory holes 902₀, 902₅, 902₈ and 902₁₃ are classified herein as “first quarter memory holes,” memory holes 902₁, 902₄, 902₉ and 902₁₂ are classified herein as “second quarter memory holes,” memory holes 902₂, 902₇, 902₁₀ and 902₁₅ are classified herein as “third quarter memory holes,” and memory holes 902₃, 902₆, 902₁₁ and 902₁₄ are classified herein as “fourth quarter memory holes.”

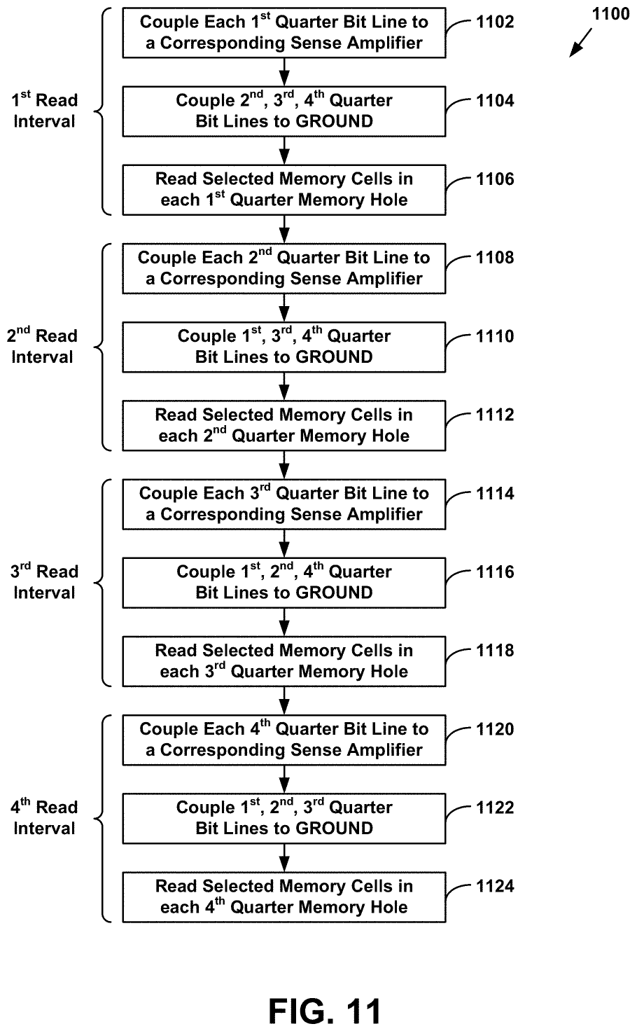

FIG. 11 is a flowchart describing an embodiment of a process 1100 for performing QBL voltage sensing. In an example embodiment, process 1100 is performed on memory die 106 (FIG. 1) using the control circuit discussed above. For example, process 1100 can be performed at the direction of state machine 216 (FIG. 2). In the embodiment of QBL voltage sensing depicted in process 1100, selected memory cells in memory holes 902₀, 902₁, 902₂, . . . , 902₁₅ are read in four separate read intervals. Without wanting to be bound by any particular theory, it is believed that reading the selected memory cells in memory holes 902₀, 902₁, 902₂, . . . , 902₁₅ in four separate read intervals may reduce effects of parasitic capacitance between adjacent memory holes 902₀, 902₁, 902₂, . . . , 902₁₅.

In step 1102, in a first read interval, each of first quarter bit lines B₀, B₅, B₈ and B₁₃ is coupled to a corresponding one of four sense amplifiers (e.g., sense amplifiers SA0, SA1, SA2 and SA3, respectively). In step 1104, second quarter bit lines B₁, B₄, B₉ and B₁₂, third quarter bit lines B₂, B₇, B₁₀ and B₁₅, and fourth quarter bit lines B₃, B₆, B₁₁ and B₁₄ are coupled to GROUND (or some other predetermined voltage). In step 1106, the selected memory cells of first quarter memory holes 902₀, 902₅, 902₈ and 902₁₃ are read.

In step 1108, in a second read interval, each of second quarter bit lines B₁, B₄, B₉ and B₁₂, is coupled to a corresponding one of four sense amplifiers (e.g., sense amplifiers SA0, SA1, SA2 and SA3, respectively). In step 1110, first quarter bit lines B₀, B₅, B₈ and B₁₃, third quarter bit lines B₂, B₇, B₁₀ and B₁₅, and fourth quarter bit lines and B₃, B₆, B₁₁ and B₁₄ are coupled to GROUND (or some other predetermined voltage). In step 1112, the selected memory cells of second quarter memory holes 902₁, 902₄, 902₉ and 902₁₂ are read.

In step 1114, in a third read interval, each of third quarter bit lines B₂, B₇, B₁₀ and B₁₅ is coupled to a corresponding one of four sense amplifiers (e.g., sense amplifiers SA0, SA1, SA2 and SA3, respectively). In step 1116, first quarter bit lines B₀, B₅, B₈ and B₁₃, second quarter bit lines B₁, B₄, B₉ and B₁₂, and fourth quarter bit lines B₃, B₆, B₁₁ and B₁₄ are coupled to GROUND (or some other predetermined voltage). In step 1118, the selected memory cells of third quarter memory holes 902₂, 902₇, 902₁₀ and 902₁₅ are read.

In step 1120, in a fourth read interval, each of fourth quarter bit lines B₃, B₆, B₁₁ and B₁₄ is coupled to a corresponding one of four sense amplifiers (e.g., sense amplifiers SA0, SA1, SA2 and SA3, respectively). In step 1122, first quarter bit lines B₀, B₅, B₈ and B₁₃, second quarter bit lines B₁, B₄, B₉ and B₁₂, and third quarter bit lines B₂, B₇, B₁₀ and B₁₅ are coupled to GROUND (or some other predetermined voltage). In step 1124, the selected memory cells of fourth quarter memory holes 902₃, 902₆, 902₁₁ and 902₁₄ are then read.

Note that example process described above and illustrated in FIG. 11 depicts process steps that would be implemented in a scenario in which selected memory cells in each of first quarter memory holes 902₀, 902₅, 902₈ and 902₁₃, second quarter memory holes 902₁, 902₄, 902₉ and 902₁₂, third quarter memory holes 902₂, 902₇, 902₁₀ and 902₁₅, and fourth quarter memory holes 902₃, 902₆, 902₁₁ and 902₁₄ are read (e.g., in response to a host read request for selected memory cells in all four quarters). Often the host requires only part of the quarter, in which case only the necessary quarter is read (e.g., if the user-requested data is in third quarter, only the third quarter is read).

Referring again to FIG. 10A, the memory holes in each segment are separated from one another by an intervening memory hole from outside the segment. For example, each of first quarter memory holes 902₀, 902₅, 902₈ and 902₁₃ are separated from one another by at least one intervening memory hole not included in the segment of first quarter memory holes 902₀, 902₅, 902₈ and 902₁₃. In particular, first quarter memory holes 902₀ and 902₅ are separated by third quarter memory hole 902₂, first quarter memory holes 902₀ and 902₈ are separated by second quarter memory hole 902₄, first quarter memory holes 902₅ and 902₈ are separated by fourth quarter memory hole 902₆, first quarter memory holes 902₅ and 902₁₃ are separated by second quarter memory hole 902₉, and first quarter memory holes 902₈ and 902₁₃ are separated by third quarter memory hole 902₁₀. Without wanting to be bound by any particular theory, it is believed that parasitic capacitance between first quarter memory holes 902₀, 902₅, 902₈ and 902₁₃ is much lower than parasitic capacitance between adjacent selected memory holes in an HBL shielded voltage sensing technique (e.g., parasitic capacitances Cp₀₂, Cp₂₄, Cp₁₃ and Cp₃₅ in FIG. 9C), and thus during the first quarter read interval the effects of parasitic capacitive coupling are substantially reduced.

In addition, each of second quarter memory holes 902₁, 902₄, 902₉ and 902₁₂ are separated from one another by at least one intervening memory hole not included in the segment of second quarter memory holes 902₁, 902₄, 902₉ and 902₁₂. In particular, second quarter memory holes 902₁ and 902₄ are separated by third quarter memory hole 902₂, second quarter memory holes 902₁ and 902₉ are separated by first quarter memory hole 902₅, second quarter memory holes 902₄ and 902₉ are separated by fourth quarter memory hole 902₆, second quarter memory holes 902₄ and 902₁₂ are separated by first quarter memory hole 902₈, and second quarter memory holes 902₉ and 902₁₂ are separated by third quarter memory hole 902₁₀. Without wanting to be bound by any particular theory, it is believed that parasitic capacitance between second quarter memory holes 902₁, 902₄, 902₉ and 902₁₂ is much lower than parasitic capacitance between adjacent selected memory holes in an HBL shielded voltage sensing technique (e.g., parasitic capacitances Cp₀₂, Cp₂₄, Cp₁₃ and Cp₃₅ in FIG. 9C), and thus during the second quarter read interval the effects of parasitic capacitive coupling are substantially reduced.

Further, each of third quarter memory holes 902₂, 902₇, 902₁₀ and 902₁₅ are separated from one another by at least one intervening memory hole not included in the segment of third quarter memory holes 902₂, 902₇, 902₁₀ and 902₁₅. In particular, third quarter memory holes 902₂ and 902₇ are separated by first quarter memory hole 902₅, third quarter memory holes 902₂ and 902₁₀ are separated by fourth quarter memory hole 902₆, third quarter memory holes 902₇ and 902₁₀ are separated by second quarter memory hole 902₉, third quarter memory holes 902₇ and 902₁₅ are separated by fourth quarter memory hole 902₁₁, and third quarter memory holes 902₁₀ and 902₁₅ are separated by first quarter memory hole 902₁₃. Without wanting to be bound by any particular theory, it is believed that parasitic capacitance between third quarter memory holes 902₂, 902₇, 902₁₀ and 902₁₅ is much lower than parasitic capacitance between adjacent selected memory holes in an HBL shielded voltage sensing technique (e.g., parasitic capacitances Cp₀₂, Cp₂₄, Cp₁₃ and Cp₃₅ in FIG. 9C), and thus during the third quarter read interval the effects of parasitic capacitive coupling are substantially reduced.

Moreover, each of fourth quarter memory holes 902₃, 902₆, 902₁₁ and 902₁₄ are separated from one another by at least one intervening memory hole not included in the segment of fourth quarter memory holes 902₃, 902₆, 902₁₁ and 902₁₄. In particular, fourth quarter memory holes 902₃ and 902₆ are separated by first quarter memory hole 902₅, fourth quarter memory holes 902₃ and 902₁₁ are separated by third quarter memory hole 902₇, fourth quarter memory holes 902₆ and 902₁₁ are separated by second quarter memory hole 902₉, fourth quarter memory holes 902₆ and 902₁₄ are separated by third quarter memory hole 902₁₀, and fourth quarter memory holes 902₁₁ and 902₁₄ are separated by first quarter memory hole 902₁₃. Without wanting to be bound by any particular theory, it is believed that parasitic capacitance between fourth quarter memory holes 902₃, 902₆, 902₁₁ and 902₁₄ is much lower than parasitic capacitance between adjacent selected memory holes in an HBL shielded voltage sensing technique (e.g., parasitic capacitances Cp₀₂, Cp₂₄, Cp₁₃ and Cp₃₅ in FIG. 9C), and thus during the fourth quarter read interval the effects of parasitic capacitive coupling are substantially reduced.

Without wanting to be bound by any particular theory, it is believed that parasitic capacitive coupling between selected memory columns in the QBL voltage sensing technique described above is much lower than that of previously known HBL shielded voltage sensing techniques such as those described above.

FIG. 10B depicts a top-down view of an embodiment of a portion of a three-dimensional memory array that includes a group 900d of sixteen bit lines B₀, B₁, B₂, . . . B₁₅ and sixteen memory holes 902₀, 902₁, 902₂, . . . , 902₁₅, each including a NAND string of memory cells. In an embodiment, each of memory holes 902₀, 902₁, 902₂, . . . , 902₁₅ is associated with and coupled to a corresponding one of bit lines B₀, B₁, B₂, . . . B₁₅. Bit lines B₀, B₁, B₂, . . . , B₁₅, (and associated and memory holes 902₀, 902₁, 902₂, . . . , 902₁₅) are conceptually divided into four segments. As in the example embodiment of FIG. 10A, group 900d includes first quarter bit lines B₀, B₅, B₈ and B₁₃, second quarter bit lines B₁, B₄, B₉ and B₁₂, third quarter bit lines B₂, B₇, B₁₀ and B₁₅, and fourth quarter bit lines B₃, B₆, B₁₁ and B₁₄, and includes first quarter memory holes 902₀, 902₅, 902₈ and 902₁₃, second quarter memory holes 902₁, 902₄, 902₉ and 902₁₂, third quarter memory holes 902₂, 902₇, 902₁₀ and 902₁₅, and fourth quarter memory holes 902₃, 902₆, 902₁₁ and 902₁₄.

In an embodiment of QBL voltage sensing, selected memory cells in memory holes 902₀, 902₁, 902₂, . . . , 902₁₅ are read in four separate read intervals. Process 1100 of FIG. 11 may be used to implement the four read intervals.

In step 1102, in a first read interval, each of first quarter bit lines B₀, B₅, B₈ and B₁₃ is coupled to a corresponding one of four sense amplifiers (e.g., sense amplifiers SA0, SA1, SA2 and SA3, respectively). In step 1104, second quarter bit lines B₁, B₄, B₉ and B₁₂, third quarter bit lines B₂, B₇, B₁₀ and B₁₅, and fourth quarter bit lines B₃, B₆, B₁₁ and B₁₄ are coupled to GROUND (or some other predetermined voltage). In step 1106, the selected memory cells of first quarter memory holes 902₁, 902₄, 902₉ and 902₁₂ are read.

In step 1108, in a second read interval, each of second quarter bit lines B₁, B₄, B₉ and B₁₂, is coupled to a corresponding one of four sense amplifiers (e.g., sense amplifiers SA0, SA1, SA2 and SA3, respectively). In step 1110, first quarter bit lines B₀, B₅, B₈ and B₁₃, third quarter bit lines B₂, B₇, B₁₀ and B₁₅, and fourth quarter bit lines and B₃, B₆, B₁₁ and B₁₄ are coupled to GROUND (or some other predetermined voltage). In step 1112, the selected memory cells of second quarter memory holes 902₀, 902₅, 902₈ and 902₁₃ are read.

In step 1114, in a third read interval, each of third quarter bit lines B₂, B₇, B₁₀ and B₁₅ is coupled to a corresponding one of four sense amplifiers (e.g., sense amplifiers SA0, SA1, SA2 and SA3, respectively). In step 1116, first quarter bit lines B₀, B₅, B₈ and B₁₃, second quarter bit lines B₁, B₄, B₉ and B₁₂, and fourth quarter bit lines B₃, B₆, B₁₁ and B₁₄ are coupled to GROUND (or some other predetermined voltage). In step 1118, the selected memory cells of third quarter memory holes 902₃, 902₆, 902₁₁ and 902₁₄ are read.

In step 1120, in a fourth read interval, each of fourth quarter bit lines B₃, B₆, B₁₁ and B₁₄ is coupled to a corresponding one of four sense amplifiers (e.g., sense amplifiers SA0, SA1, SA2 and SA3, respectively). In step 1122, first quarter bit lines B₀, B₅, B₈ and B₁₃, second quarter bit lines B₁, B₄, B₉ and B₁₂, and third quarter bit lines B₂, B₇, B₁₀ and B₁₅ are coupled to GROUND (or some other predetermined voltage). In step 1124, the selected memory cells of fourth quarter memory holes 902₂, 902₇, 902₁₀ and 902₁₅ are read.

Referring again to FIG. 10B, the memory holes in each segment are separated from one another by an intervening memory hole from outside the segment. For example, each of first quarter memory holes 902₁, 902₄, 902₉ and 902₁₂ are separated from one another by at least one intervening memory hole not included in the segment of first quarter memory holes 902₁, 902₄, 902₉ and 902₁₂. In particular, first quarter memory holes 902₁ and 902₄ are separated by fourth quarter memory hole 902₂, first quarter memory holes 902₁ and 902₉ are separated by second quarter memory hole 902₅, first quarter memory holes 902₄ and 902₉ are separated by third quarter memory hole 902₆, first quarter memory holes 902₄ and 902₁₂ are separated by second quarter memory hole 902₈, and first quarter memory holes 902₉ and 902₁₂ are separated by fourth quarter memory hole 902₁₀. Without wanting to be bound by any particular theory, it is believed that parasitic capacitance between first quarter memory holes 902₁, 902₄, 902₉ and 902₁₂ is much lower than parasitic capacitance between adjacent selected memory holes in an HBL shielded voltage sensing technique (e.g., parasitic capacitances Cp₀₂, Cp₂₄, Cp₁₃ and Cp₃₅ in FIG. 9C), and thus during the first quarter read interval the effects of parasitic capacitive coupling are substantially reduced.

In addition, each of second quarter memory holes 902₀, 902₅, 902₈ and 902₁₃ are separated from one another by at least one intervening memory hole not included in the segment of second quarter memory holes 902₀, 902₅, 902₈ and 902₁₃. For example, second quarter memory holes 902₀ and 902₅ are separated by fourth quarter memory hole 902₂, second quarter memory holes 902₀ and 902₈ are separated by first quarter memory hole 902₄, second quarter memory holes 902₅ and 902₈ are separated by third quarter memory hole 902₆, second quarter memory holes 902₅ and 902₁₃ are separated by first quarter memory hole 902₉, and second quarter memory holes 902₈ and 902₁₃ are separated by fourth quarter memory hole 902₁₀. Without wanting to be bound by any particular theory, it is believed that parasitic capacitance between second quarter memory holes 902₀, 902₅, 902₈ and 902₁₃ is much lower than parasitic capacitance between adjacent selected memory holes in an HBL shielded voltage sensing technique (e.g., parasitic capacitances Cp₀₂, Cp₂₄, Cp₁₃ and Cp₃₅ in FIG. 9C), and thus during the second quarter read interval the effects of parasitic capacitive coupling are substantially reduced.

Further, each of third quarter memory holes 902₃, 902₆, 902₁₁ and 902₁₄ are separated from one another by at least one intervening memory hole not included in the segment of third quarter memory holes 902₃, 902₆, 902₁₁ and 902₁₄. For example, third quarter memory holes 902₃ and 902₆ are separated by second quarter memory hole 902₅, third quarter memory holes 902₃ and 902₁₁ are separated by fourth quarter memory hole 902₇, third quarter memory holes 902₆ and 902₁₁ are separated by first quarter memory hole 902₉, third quarter memory holes 902₆ and 902₁₄ are separated by fourth quarter memory hole 902₁₀, and third quarter memory holes 902₁₁ and 902₁₄ are separated by second quarter memory hole 902₁₃. Without wanting to be bound by any particular theory, it is believed that parasitic capacitance between third quarter memory holes 902₃, 902₆, 902₁₁ and 902₁₄ is much lower than parasitic capacitance between adjacent selected memory holes in an HBL shielded voltage sensing technique (e.g., parasitic capacitances Cp₀₂, Cp₂₄, Cp₁₃ and Cp₃₅ in FIG. 9C), and thus during the third quarter read interval the effects of parasitic capacitive coupling are substantially reduced.

Moreover, each of fourth quarter memory holes 902₂, 902₇, 902₁₀ and 902₁₅ are separated from one another by at least one intervening memory hole not included in the segment of fourth quarter memory holes 902₂, 902₇, 902₁₀ and 902₁₅. For example, fourth quarter memory holes 902₂ and 902₇ are separated by second quarter memory hole 902₅, fourth quarter memory holes 902₂ and 902₁₀ are separated by third quarter memory hole 902₆, fourth quarter memory holes 902₇ and 902₁₀ are separated by first quarter memory hole 902₉, fourth quarter memory holes 902₇ and 902₁₅ are separated by third quarter memory hole 902₁₁, and fourth quarter memory holes 902₁₀ and 902₁₅ are separated by second quarter memory hole 902₁₃. Without wanting to be bound by any particular theory, it is believed that parasitic capacitance between fourth quarter memory holes 902₂, 902₇, 902₁₀ and 902₁₅ is much lower than parasitic capacitance between adjacent selected memory holes in an HBL shielded voltage sensing technique (e.g., parasitic capacitances Cp₀₂, Cp₂₄, Cp₁₃ and Cp₃₅ in FIG. 9C), and thus during the fourth quarter read interval the effects of parasitic capacitive coupling are substantially reduced.

Without wanting to be bound by any particular theory, it is believed that parasitic capacitive coupling between selected memory columns in the QBL voltage sensing technique described above is much lower than that of previously known HBL shielded voltage sensing techniques such as those described above.

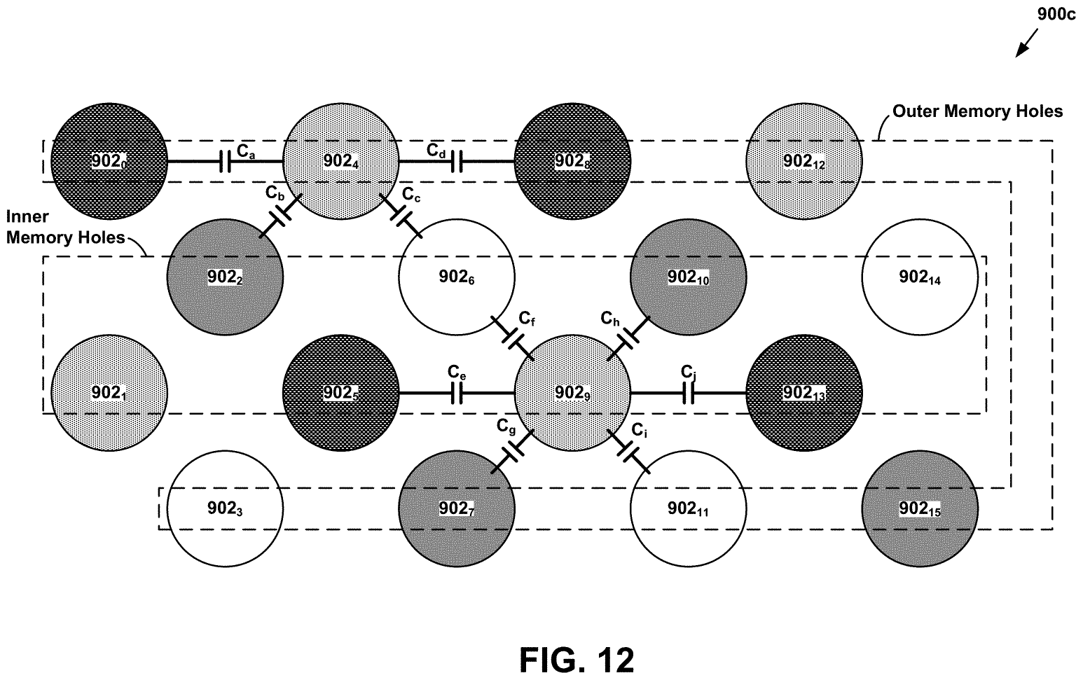

FIG. 12 depicts an enlarged top-down view a portion of a three-dimensional memory array that includes a group 900c of FIG. 10A, but with bit lines B₀, B₁, B₂, . . . B₁₅ removed to avoid overcrowding the drawing. In this view, memory holes 902₀, 902₁, 902₂, . . . , 902₁₅ are separated into “outer” memory holes 902₀, 902₃, 902₄, 902₇, 902₈, 902₁₁, 902₁₂ and 902₁₅ and “inner” memory holes 902₁, 902₂, 902₅, 902₆, 902₉, 902₁₀, 902₁₃ and 902₁₄. Outer memory holes 902₀, 902₃, 902₄, 902₇, 902₈, 902₁₁, 902₁₂ and 902₁₅ are disposed along upper and lower rows of group 900c, whereas inner memory holes 902₁, 902₂, 902₅, 902₆, 902₉, 902₁₀, 902₁₃ and 902₁₄ are disposed along interior rows of group 900c. It is believed that outer memory holes have lower parasitic capacitance between adjacent memory holes than do inner memory holes.

For example, considering only parasitic capacitance to nearest neighboring adjacent memory holes, outer memory hole 902₄ has a first parasitic capacitance cₐ to memory hole 902₀, a second parasitic capacitance c_{b} to memory hole 902₂, a third parasitic capacitance c_{c} to memory hole 902₆, and a fourth parasitic capacitance c_{d} to memory hole 902₈. In contrast, inner memory hole 902₉ has a first parasitic capacitance cₑ to memory hole 902₅, a second parasitic capacitance c_{f} to memory hole 902₆, a third parasitic capacitance c_{g} to memory hole 902₇, a fourth parasitic capacitance cₕ to memory hole 902₁₀, a fifth parasitic capacitance ci to memory hole 902₁₁, and a sixth parasitic capacitance cⱼ to memory hole 902₁₃. If all parasitic capacitance values are approximately the same (i.e., cₐ≈c_{b}≈c_{c}≈c_{d}≈cₑ≈c_{f}≈c_{g}≈cₕ≈cᵢ≈cⱼ), the capacitance of each of inner memory holes 902₁, 902₂, 902₅, 902₆, 902₉, 902₁₀, 902₁₃ and 902₁₄ is approximately fifty percent greater than that of each of outer memory holes 902₀, 902₃, 902₄, 902₇, 902₈, 902₁₁, 902₁₂ and 902₁₅.

Because inner memory holes have greater parasitic capacitance than outer memory holes, bit lines coupled to inner memory holes can become a bottleneck to achieving fast bit line settling time t_{BL}. One technique to alleviate this problem is sometimes referred to as “outer/inner bit line averaging,” in which multiple groups (e.g., group 900c of FIG. 12) are disposed adjacent to and coupled to one another, with each successive group shifted by one bit line position to the left of the previous group. For QBL voltage sensing, a shift-by-one bit line strategy would result in at least some memory holes being adjacent to another memory hole from the same segment (e.g., one or more of first quarter memory holes 902₀, 902₅, 902₈ and 902₁₃ would be directly adjacent one another), and thus would conflict with the goal of achieving a fast bit line settling time t_{BL}.

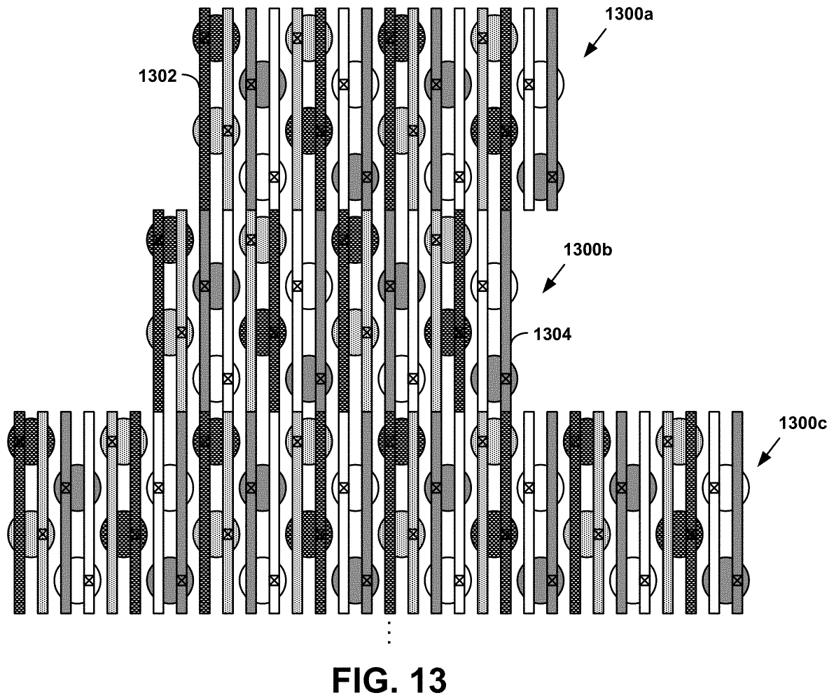

FIG. 13 depicts a top-down view of a portion of a three-dimensional memory array that includes multiple groups 1300a, 1300b, 1300c, . . . , that are disposed adjacent to and coupled to one another, with each successive group shifted to achieve an embodiment of outer/inner bit line averaging for QBL voltage sensing, such as those described above. Each of groups 1300a, 1300b, 1300c, . . . includes multiple bit lines and multiple memory holes , each including a NAND string of memory cells. To avoid overcomplicating the drawing, bit line labels and memory hole labels have been omitted. In an embodiment, groups 1300a, 1300b, 1300c, . . . are staggered in a repeating pattern of shift-by-two bit lines, shift-by-six bit lines, shift-by-two bit lines, shift-by-six bit lines, . . . .

As depicted in FIG. 13, group 1300b is shifted by two bit lines to the left of group 1300a, group 1300c is shifted six bit lines to the left of group 1300b, and so on. As a result of this repeating shifting pattern, each bit line is coupled to outer memory holes in one group, inner memory holes in a subsequent group, outer memory holes in the next subsequent group, and so on, so that each bit line has the same capacitive load. For example, bit line 1302 is coupled to an outer memory hole in group 1300a, an inner memory hole in group 1300b, an outer memory hole in group 1300c, and so on. Similarly, bit line 1304 is coupled to an inner memory hole in group 1300a, an outer memory hole in group 1300b, an inner memory hole in group 1300c, and so on.

One embodiment includes an apparatus that includes a plurality of non-volatile memory cells, a plurality of bit lines, a plurality of memory holes, and a control circuit. The plurality of memory holes each include a corresponding one of the memory cells. Each memory hole is associated with and coupled to a corresponding one of the bit lines. The control circuit is configured to read the memory cells in four separate read intervals.

One embodiment includes a method including reading a plurality of non-volatile memory cells each disposed in a corresponding one of a plurality of memory holes, each memory hole associated with and coupled to a corresponding one of a plurality of bit lines, by in a first read interval, coupling a first segment of the bit lines to a corresponding one of a plurality of sense amplifiers, in a second read interval, coupling a second segment of the bit lines to a corresponding one of the plurality of sense amplifiers, in a third read interval, coupling a third segment of the lines to a corresponding one of the plurality of sense amplifiers, and in a fourth read interval, coupling a fourth segment of the bit lines to a corresponding one of the plurality of sense amplifiers.

One embodiment includes an apparatus that includes a first group of first memory holes and first bit lines, a second group of second memory holes and second bit lines, and a third group of third memory holes and third bit lines. Each first memory hole is associated with and coupled to a corresponding one of the first bit lines. The first memory holes include four segments of first memory holes, and the first memory holes in each segment are separated from one another by an intervening first memory hole from outside the segment. Each second memory hole is associated with and coupled to a corresponding one of the second bit lines. The second memory holes include four segments of second memory holes, and the second memory holes in each segment are separated from one another by an intervening second memory hole from outside the segment. Each third memory hole is associated with and coupled to a corresponding one of the third bit lines. The third memory holes include four segments of third memory holes. The third memory holes in each segment are separated from one another by an intervening third memory hole from outside the segment. The second group of second bit lines is disposed adjacent to and coupled to the first group of first bit lines. The third group of third bit lines is disposed adjacent to and coupled to the second group of second bit lines, the second group of second bit lines is shifted by two bit lines relative to the first group of first bit lines. The third group of third bit lines is shifted by six bit lines relative to the second group of second bit lines.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

1. An apparatus comprising:
a plurality of non-volatile memory cells;
a plurality of bit lines;
a plurality of memory holes each comprising a corresponding one of the memory cells, each memory hole associated with and coupled to a corresponding one of the bit lines; and
a control circuit configured to read the memory cells in four separate read intervals.

2. The apparatus of claim 1, wherein the memory cells comprise four segments of memory cells, and the control circuit is configured to read each segment of memory cells in a corresponding one of the four separate read intervals.

3. The apparatus of claim 1, wherein:
the memory holes comprise four segments of memory holes; and
the memory holes in each segment are separated from one another by an intervening memory hole from outside the segment.

4. The apparatus of claim 1, wherein:
the memory holes comprise four segments of memory holes; and
the control circuit is configured to couple the bit lines associated with the memory holes in each segment to a corresponding one of a plurality of sense amplifiers.

5. The apparatus of claim 1, wherein:
the memory holes comprise four segments of memory holes; and
the control circuit is configured during each of the four read intervals to couple the bit lines associated with the memory holes in a corresponding one of the segments to a corresponding one of a plurality of sense amplifiers, and couple the bit lines associated with the memory holes in all other segments to GROUND.

6. The apparatus of claim 1, wherein the control circuit is configured to read the memory cells in four separate read intervals to reduce effects of parasitic capacitance between adjacent memory holes.

7. The apparatus of claim 1, further comprising alternating dielectric layers and word line layers, wherein each of the plurality of memory holes is formed in the stack of alternating dielectric layers and conductive layers.

8. The apparatus of claim 1, wherein each of the plurality of memory holes comprises a vertical column of memory cells.

9. The apparatus of claim 1, wherein each of the plurality of memory holes comprises a NAND string.

10. The apparatus of claim 1, wherein the plurality of non-volatile memory cells comprise a three-dimensional memory array.

11. A method comprising:
reading a plurality of non-volatile memory cells each disposed in a corresponding one of a plurality of memory holes, each memory hole associated with and coupled to a corresponding one of a plurality of bit lines, by:
in a first read interval, coupling a first segment of the bit lines to a corresponding one of a plurality of sense amplifiers;
in a second read interval, coupling a second segment of the bit lines to a corresponding one of the plurality of sense amplifiers;
in a third read interval, coupling a third segment of the lines to a corresponding one of the plurality of sense amplifiers; and
in a fourth read interval, coupling a fourth segment of the bit lines to a corresponding one of the plurality of sense amplifiers.

12. The method of claim 11, wherein:
each of the first segment of bit lines is coupled to a corresponding first segment of the memory holes;
each of the second segment of bit lines is coupled to a corresponding second segment of the memory holes;
each of the third segment of bit lines is coupled to a corresponding third segment of the memory holes;
each of the fourth segment of bit lines is coupled to a corresponding fourth segment of the memory holes; and
the memory holes in each segment of the memory holes are separated from one another by an intervening memory hole from outside the segment of the memory holes.

13. The method of claim 11, further comprising:
in the first read interval, coupling each of the second segment of the bit lines, the third segment of the bit lines, and the fourth segment of the bit lines to GROUND;
in the second read interval, coupling each of the first segment of the bit lines, the third segment of the bit lines, and the fourth segment of the bit lines to GROUND;
in the third read interval, coupling each of the first segment of the bit lines, the second segment of the bit lines, and the fourth segment of the bit lines to GROUND; and
in the fourth read interval, coupling each of the first segment of the bit lines, the second segment of the bit lines, and the third segment of the bit lines to GROUND.

14. The method of claim 11, wherein each of the memory holes is formed in a stack of alternating dielectric layers and conductive layers.

15. The method of claim 11, wherein each of the memory holes comprises a vertical column of memory cells.

16. The method of claim 11, wherein each of the memory holes comprises a NAND string.

17. The method of claim 11, wherein the plurality of non-volatile memory cells comprise a three-dimensional memory array.

18. An apparatus comprising:
a first group of first memory holes and first bit lines, each first memory hole associated with and coupled to a corresponding one of the first bit lines, the first memory holes comprising four segments of first memory holes, wherein the first memory holes in each segment are separated from one another by an intervening first memory hole from outside the segment;
a second group of second memory holes and second bit lines, each second memory hole associated with and coupled to a corresponding one of the second bit lines, the second memory holes comprising four segments of second memory holes, wherein the second memory holes in each segment are separated from one another by an intervening second memory hole from outside the segment; and
a third group of third memory holes and third bit lines, each third memory hole associated with and coupled to a corresponding one of the third bit lines, the third memory holes comprising four segments of third memory holes, wherein the third memory holes in each segment are separated from one another by an intervening third memory hole from outside the segment,
wherein the second group of second bit lines is disposed adjacent to and coupled to the first group of first bit lines, the third group of third bit lines is disposed adjacent to and coupled to the second group of second bit lines, the second group of second bit lines is shifted by two bit lines relative to the first group of first bit lines, and the third group of third bit lines is shifted by six bit lines relative to the second group of second bit lines.

19. The apparatus of claim 18, wherein each of the first memory holes, second memory holes and third memory holes comprises a vertical column of memory cells.

20. The apparatus of claim 18, wherein each of the first memory holes, second memory holes and third memory holes comprises a NAND string.
